(19) United States
(12) Patent Application Publication
(10) Pub. No.: US 2026/0276574 A1
(43) Pub. Date: Sep. 17, 2026

(54) DEVICE FOR IMAGING AND ELECTROCHEMICAL SENSING

(71) Applicant: THE BOARD OF TRUSTEES OF THE UNIVERSITY OF ALABAMA, Tuscaloosa, AL (US)

(72) Inventors: Shanlin Pan, Tuscaloosa, AL (US); Md Ashaduzzaman, Tuscaloosa, AL (US)

(21) Appl. No.: 19/194,307

(22) Filed: Apr. 30, 2025

Related U.S. Application Data
(60) Provisional application No. 63/666,327, filed on Jul. 1, 2024.

(51) Int. Cl. G01N 27/28; G01N 27/30; G01Q 60/38; H03H 9/215

(52) U.S. Cl. CPC G01N 27/283; G01N 27/301; G01Q 60/38; H03H 9/215

(57) ABSTRACT

The disclosure is directed to a device comprising: a piezoelectric resonator; and a micro or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter, wherein the predetermined length is measured from a coupling point to the piezoelectric resonator, wherein the body of the micro or nano-sized reservoir comprises: (a) a first electrode; and (b) an electrolyte solution configured to at least partially disperse as a droplet from the tip on a surface of a substrate; wherein the predetermined length is selected to provide a Q-factor of the piezoelectric resonator of 500 Hz to 10 KHz.

### CROSS-REFERENCE TO RELATED APPLICATIONS

This application claims the benefit of U.S. Provisional Application No. 63/666,327, filed on Jul. 1, 2024, the contents of which are incorporated herein by reference in their entirety.

### STATEMENT ACKNOWLEDGING GOVERNMENT SUPPORT

This invention was made with government support under Grant No. 2113505 awarded by the National Science Foundation. The government has certain rights in the invention.

### BACKGROUND

Scanning Electrochemical Cell Microscopy (SECCM) is a versatile scanning probe microscopy technique capable of revealing the redox activity of nanostructured electrocatalysts with high special resolution. However, constant height or current SECCM surface mapping is unsuitable for rough surfaces and surfaces with locally heterogeneous conductivity due to tip damage during the scanning. The hopping mode technique has recently been reintroduced in SECCM to address this limitation. However, the hopping-scanning approach is slow and takes several hours to resolve electrochemical information. Moreover, SECCM is limited in providing accurate topographical information on the sample surface, as it utilizes current as the feedback signal. Additionally, it is challenging to study less conductive or nonconductive surfaces with SECCM. The recent utilization of a micrometer-sized dual barrel scanning probe would only help eliminate the need for a conductive surface with lower spatial resolution than conventional SECCM operation configuration. Therefore, developing a new technique capable of resolving surface morphology and fast local redox activity is still needed.

Such and other needs, at least partially, are addressed by the current disclosure.

### SUMMARY OF THE DISCLOSURE

The present disclosure is directed to a device comprising: a piezoelectric resonator; and a micro or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter, wherein the predetermined length is measured from a coupling point to the piezoelectric resonator, wherein the body of the micro or nano-sized reservoir comprises: (a) a first electrode; and (b) an electrolyte solution configured to at least partially disperse as a droplet from the tip on a surface of a substrate; wherein the predetermined length is selected to provide a Q-factor of the piezoelectric resonator of 500 Hz to 10 KHz.

Also disclosed is a device comprising: a piezoelectric resonator; and a micro- or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter, wherein the predetermined length is measured from a coupling point to the piezoelectric resonator, wherein at least a portion of an interior portion of the body of the micro or nano-sized reservoir and/or at least a portion of an interior portion of the tip comprises a conductive material; wherein the body of the micro or nano-sized reservoir comprises an electrode; wherein the predetermined length is selected to provide a Q-factor of the piezoelectric resonator of 500 Hz to 10 KHz; a distance from the tip to the substrate surface is controlled by the piezoelectric resonator; and wherein the device is operated in a shear force mode, tapping mode, or a combination thereof.

Also disclosed herein is a system comprising any of the disclosed herein devices.

Still further disclosed herein is a mounting device comprising: a first portion configured to receive an atomic-force microscope (AFM) probe, wherein the AFM probe comprises a tuning fork comprising two prongs; a second portion configured to receive a micro or nano-sized reservoir; the first and the second portions are aligned with each other such that when the tuning fork is mounted within the first portion, and the micro or nano-sized reservoir is mounted within the second portion, the micro or nano-sized reservoir is positioned substantially vertically to a distal end of one of the two prongs of the tuning fork.

Also disclosed herein are systems comprising any of the disclosed herein mounting devices.

Still further disclosed herein is a method comprising: positioning a sample within the system comprising any of the disclosed herein devices, measuring at least one property of the sample, wherein the at least one property is selected from the sample roughness, topography, electrical response, electrochemical response, photocurrent, or a combination thereof.

Yet still further disclosed herein is a method of forming a micro or nano-sized reservoir comprising: pulling a capillary tube to obtain a micro or nanopipette having a body and a tip, wherein the tip is defined by a predetermined aperture diameter and the body has a predetermined length; filling the body of the micro or nanopipette with an electrolyte solution such that the tip is substantially free of air bubbles.

In yet still further aspects, disclosed herein is a method comprising positioning a tuning fork and a micro or nano-sized reservoir in any of the disclosed herein mounting devices, and coupling the nano-sized reservoir to the tuning fork, wherein the coupling is monitored by a dual-camera system.

Also disclosed herein is a method of using any of the disclosed herein devices of systems. In certain aspects, disclosed is a method comprising: obtaining an AF morphology image of a sample at open circuit potential, wherein the image comprises one or more regions of interest (ROIs); moving any of the disclosed herein devices to the one or more regions of interest; collecting a cycling voltammetry at the one or more regions of interest to probe a local redox activity.

Additional aspects of the disclosure will be set forth, in part, in the detailed description, figures, and claims that follow, and in part, will be derived from the detailed description or can be learned by practice of the invention. It is to be understood that both the foregoing general description and the following detailed description are exemplary and explanatory only and are not restrictive of the invention as disclosed.

### BRIEF DESCRIPTION OF THE DRAWINGS

These and other features, aspects, and advantages of the present invention will become apparent from the following description and the accompanying exemplary implementations shown in the drawings, which are briefly described below.

FIGS. 1A-1C is a schematic diagram of an exemplary imaging and sensing device (FIG. 1A and FIG. 1C) and a photograph of an exemplary portion of the device (FIG. 1B).

FIGS. 2A-2E show a schematic diagram of various configurations of an exemplary imaging and sensing device.

FIGS. 3A-3E show a schematic diagram of an exemplary mounting device according to one aspect of the disclosure (FIG. 3A), an image of the laboratory setup featuring dual-camera tip attachment system, including side and rear views (FIG. 3B), side camera view of the glue attached tuning fork (FIG. 3C), side camera view of the focused reservoir before moving the AFM probe holder (FIG. 3D) and side camera view of the reservoir after attachment with the tuning fork prong (FIG. 3E).

FIGS. 4A-4B is a current-voltage diagram showing the ion transport through an exemplary reservoir having various aperture diameters in a 10 mM H₂SO₄ electrolyte solution. Inset is the schematic of the experimental setup (FIG. 4A) and the anodic-cathodic current dependency on the nanopipette aperture at 0.5 V and −0.5 V vs Ag quasi-reference and counter electrode (QRCE). Inset is the SEM image of the nanopipette fabricated by the laser-assisted pipette pulling system (FIG. 4B). The scan rate is 10 mV/s.

FIGS. 5A-5C show optical images of an exemplary reservoir apex length from the contact point at the tuning fork prong (FIG. 5A), resonance frequency shift depending on the elongated length (FIG. 5B), and the frequency and the Q-factor dependency on the elongated length (FIG. 5C).

FIGS. 6A-6H depict a surface topography of the indium tin oxide (ITO) (FIG. 6A) and Ag nanowire (NW) (FIG. 6B) using an exemplary reservoir attached to quartz tuning fork (QTF)-AFM (inset images are the CCD camera view of the ITO surface and Ag NWs at ITO with nanopipette, respectively), Cyclic voltammetry (CV) at different point locations at the ITO surface (FIG. 6C), distribution of peak potential of redox reactions at different point locations of the ITO (FIG. 6D), CVs at various individual Ag NW (FIG. 6E), peak potential distribution of redox reaction at different Ag NW (FIG. 6F), CVs at the intersection of multiple Ag NW (FIG. 6G), and peak potential distribution of redox reaction at various Ag NW (FIG. 6H). The electrolyte is 10 mM H₂SO₄. The scan rate is 30 mV/s.

FIGS. 7A-7C depict an SEM image of an individual Ag NW on the ITO substrate (FIG. 7A), 3D topographical mapping of an individual Ag NW on the ITO collected by scanning nanopipette-based QTF-AFM system (FIG. 7B), comparison of CVs taken at two-point locations along a single Ag NW and at a point location at ITO (FIG. 7C), and optical image of the investigated Ag NW indicating the investigated point locations collected by CCD camera.

FIG. 8 depicts a CV of bare ITO (1.0×0.5 cm²) in 10 mM H₂SO₄. The scan rate was 30 mV/s.

FIG. 9 depicts the CV of ion transfer in a nanopipette filled with 10 mM H₂SO₄ and immersed into the 10 mM H₂SO₄. The scan rate was 10 mV/s.

FIG. 10 depicts a CV at the ITO surface using the disclosed reservoir attached QTF-AFM at various potential ranges in 10 mM H₂SO₄. The scan rate was 30 mV/s.

FIGS. 11A-11B depict CV taken at point locations at individual Ag NW and point location on ITO surface (FIG. 11A), and schematic diagram illustrating the formation of microdroplet at the tip-substrate contact point exposing both Ag NW and ITO when landed at the single Ag NW, inset is the SEM image of the droplet formed at the ITO surface (FIG. 11B). Both the CVs show ITO surface oxidation peaks; however, only the CV taken at the AgNW shows characteristic Ag oxidation-reduction peaks. CV at Ag NW shows hydrogen evolution reaction (HER) at a lower overpotential than that taken on the ITO surface. The electrolyte was 10 mM H₂SO₄. The scan rate was 30 mV/s.

FIG. 12 depicts the CV of bare Ag wire (0.25 mm diameter, Thermo Fisher Scientific) in 10 mM H₂SO₄ solution. The scan rate was 30 mV/s.

FIGS. 13A-13C depict SEM images of the individual and Ag NWs bundle at the ITO substrate (FIG. 13A), charge-coupled device (CCD) camera image of the CV collection points at single Ag NW, and the intersection of multiple Ag NWs (FIG. 13B), and CVs of various point locations indicated in the image (FIG. 13B) with 10 mM H₂SO₄ by using nanopipette based QTF-AFM (FIG. 13C). The scan rate was 30 mV/s.

FIGS. 14A-14D depict a TF-SECCM topographical image of the thin MoS₂ layer on the ITO surface (FIG. 14A), SEM image of the MOS₂ top surface shows defective sites and a basal plane (FIG. 14B), line profile of the topographical image (FIG. 14C) and CVs taken at different points of interest at the surface after topographical mapping (FIG. 14D). The CVs were taken with 10 mM H₂SO₄ and with a scan rate of 30 mV/s.

FIGS. 15A-15G depict a TF-SECCM topographical image of the MoS₂ thin layer, inset is the rear view of the MoS₂ flake with CCD camera (FIG. 15A), 3D presentation of the scanned MoS₂ (FIG. 15B), Correlated SEM image of the MoS₂ after topographical mapping (FIG. 15C), line scan profile during the topographical mapping indicated by the white arrow (FIG. 15D), elemental mapping of the micro flake confirms the presence of Mo (FIG. 15E) and S (FIG. 15F), and CVs at various point of interest indicated in FIG. 15A at the scanned surface (FIG. 15F). The CVs used 10 mM H₂SO₄, and the scan rate was 30 mV/s.

FIGS. 16A-16B depict CVs at MoS₂ at various positive potential ranges, 2 consecutive cycles (FIG. 16A), and 1 cycle with different positive potential (FIG. 16B). 10 mM H₂SO₄ was used as the electrolyte, and the scan rate was 30 mV/s.

FIGS. 17A-17C depict a TF-SECCM 2D and 3D topographical image of vertically aligned edge sites; inset is the rear optical image (FIGS. 17A-17B) and CVs at various point locations (FIG. 17C).

FIGS. 18A-18F depict a SEM micrograph of the electrodeposited Cu₂O, inset is a photo of an as-grown Cu₂O (FIG. 19A); a cross-section SEM image of as-grown Cu₂O film thickness (FIG. 19B); a TF-SECCM 2D topographical mapping of the Cu₂O surface (FIG. 19C); a 3D topographic image of the surface (FIG. 19D); a TF-SECCM image of the extended area of the Cu₂O surface (FIG. 19E), and a 3D presentation of the extended area shows highly rough surface (FIG. 19F).

FIGS. 19A-19D depict a SEM micrograph of the as-prepared TiO₂ nanorod on FTO (FIG. 19A), a SEM image of the Au1@TiO₂ (FIG. 19B); a SEM image of the Au10@TiO₂ (FIG. 19C) and a SEM image of the Au50@TiO₂ (FIG. 19D).

FIG. 20 depicts a SEM image of nanopipette.

FIG. 21 depicts a schematic representation of a SECCM setup for photoelectrochemistry study.

FIG. 22 depicts a cyclic voltammogram of the electrodeposited Cu₂O film in 2 mM Na₂SO₄ solution. The arrow indicates the polarization direction. The scan rate was 30 mVs⁻¹.

FIGS. 23A-23B depict a TE-SECCM topographical image of the Cu₂O surface overlapped by photocurrent response of the specified POIs, the photocurrent response is achieved at −0.96 V under 488 nm light excitation by subtracting the dark current (FIG. 23A) and photocurrent responses under intermittent laser excitation (488 nm) at different point locations at various crystal phases indicated in FIG. 23A (FIG. 23B); the linear sweep voltammograms were collected with 1 mM Na₂SO₄ solution. The scan rate was 10 mV/s.

FIGS. 24A-24B depict a TE-SECCM topographical image of the Cu₂O surface overlapped by photocurrent response of the specified POIs, the photocurrent response is achieved at −0.96 V under 488 nm light excitation by subtracting the dark current (FIG. 24A) and photocurrent responses under intermittent laser excitation (488 nm) at different point locations at various crystal phases indicated in FIG. 24A (FIG. 24B); the linear sweep voltammograms were collected with 1 mM Na₂SO₄ solution. The scan rate was 10 mV/s.

FIGS. 25A-25B depict a TE-SECCM topographical image of the Cu₂O surface overlapped by photocurrent response of the specified POIs, the photocurrent response is achieved at −0.96 V under 488 nm light excitation by subtracting the dark current (FIG. 25A) and photocurrent responses under intermittent laser excitation (488 nm) at different point locations at various crystal phases indicated in FIG. 25A (FIG. 25B); the linear sweep voltammograms were collected with 1 mM Na₂SO₄ solution. The scan rate was 10 mV/s.

FIGS. 26A-26C depict a TF-SECCM topographical image of the TiO₂/FTO sample surface overlapped by photocurrent response, the photocurrent response is achieved by subtracting dark current at 0.74 V (FIG. 26A), a correlated SEM micrograph of the scanned region, inset is the high-resolution SEM image showing the TiO₂ NRs (FIG. 26B), and photocurrent responses under intermittent light excitation (UV) at different point locations indicated in FIG. 26A (FIG. 26C); the linear sweep voltammograms were collected with 1 mM KOH solution. The scan rate was 10 mV/s.

FIGS. 27A-27C depict a TF-SECCM topographical image of the Au1@TiO₂ sample surface overlapped by photocurrent response. The photocurrent response is achieved by subtracting dark current at 0.74 V (FIG. 27A), SEM micrograph of the scratched surface before the topographical scanning (FIG. 27B), and Photocurrent responses under intermittent light excitation (UV) at different point locations indicated in FIG. 27A (FIG. 27C); the linear sweep voltammograms were collected with 1 mM KOH solution. The scan rate was 10 mV/s.

FIGS. 28A-28C depict a TF-SECCM topographical image of the Au10@TiO₂ sample surface overlapped by photocurrent response, the photocurrent response is achieved by subtracting dark current at 0.74 V (FIG. 28A), Correlated SEM micrograph of the topographical scanned region, inset is the SEM image showing horizontally aligned TiO₂ NRs (FIG. 28B), and photocurrent responses under intermittent light excitation (UV) at different point locations indicated in FIG. 28A (FIG. 28C). The linear sweep voltammograms were collected with 1 mM KOH solution. The scan rate was 10 mV/s.

FIGS. 29A-29C depict a TF-SECCM topographical image of the Au50@TiO₂ sample surface overlapped by photocurrent response, the photocurrent response is achieved by subtracting dark current at 0.74 V (FIG. 29A), Correlated SEM micrograph of the scanned region, inset showing the presence of large Au particle at the top of the TiO₂ NR (FIG. 29B), and photocurrent responses under intermittent light excitation (UV) at different point locations indicated in FIG. 29A (FIG. 29C). The linear sweep voltammograms were collected with 1 mM KOH solution. The scan rate was 10 mV/s.

FIG. 30 depicts a schematic of the photo-induced electrochemical water splitting reaction investigation of bare and Au NPs-coated TiO₂ NR samples using the TF-SECCM system.

### DETAILED DESCRIPTION

The present invention can be understood more readily by reference to the following detailed description, examples, drawings, and claims, and their previous and following description. However, before the present assemblies, systems, and/or methods are disclosed and described, it is to be understood that this invention is not limited to the specific or exemplary aspects of assemblies, systems, and/or methods disclosed unless otherwise specified, as such can, of course, vary. It is also to be understood that the terminology used herein is for the purpose of describing particular aspects only and is not intended to be limiting.

The following description of the invention is provided as an enabling teaching of the invention in its best, currently known aspect. To this end, those skilled in the relevant art will recognize and appreciate that many changes can be made to the various aspects of the invention described herein while still obtaining the beneficial results of the present invention. It will also be apparent that some of the desired benefits of the present invention can be obtained by selecting some of the features of the present invention without utilizing other features. Accordingly, those of ordinary skill in the pertinent art will recognize that many modifications and adaptations to the present invention are possible and can even be desirable in certain circumstances and are a part of the present invention. Thus, the following description is again provided as illustrative of the principles of the present invention and not in limitation thereof.

### Definitions

As used herein, the terms “optional” or “optionally” mean that the subsequently described event or circumstance can or cannot occur and that the description includes instances where said event or circumstance occurs and instances where it does not.

It is appreciated that certain features of the disclosure, which are, for clarity, described in the context of separate aspects, can also be provided in combination with a single aspect. Conversely, various features of the disclosure, which are, for brevity, described in the context of a single aspect, can also be provided separately or in any suitable subcombination.

As used in the description and the appended claims, the singular forms “a,” “an,” and “the” include plural referents unless the context clearly dictates otherwise. Thus, for example, a reference to “a device” includes not only one but also two or more such devices, and a reference to “a reservoir” includes not only one but also two or more such reservoirs and the like.

Throughout the description and claims of this specification, the word “comprise” and other forms of the word, such as “comprising” and “comprises,” are open, non-limiting terms and mean “including but not limited to,” and are not intended to exclude, for example, other additives, segments, integers, or steps. Furthermore, it is to be understood that the terms “comprise,” “comprising,” and “comprises” as they relate to various aspects, elements, and features of the disclosed invention also include the more limited aspects of “consisting essentially of” and “consisting of.”

Unless defined otherwise, all technical and scientific terms used herein have the same meaning as commonly understood by one of ordinary skill in the art to which this invention belongs. In this specification and in the claims which follow, reference will be made to a number of terms that shall be defined herein.

For the terms “for example” and “such as” and grammatical equivalences thereof, the phrase “and without limitation” is understood to follow unless explicitly stated otherwise. It is further understood that these phrases are used for explanatory purposes only. It is further understood that the term “exemplary,” as used herein, means “an example of” and is not intended to convey an indication of a preferred or ideal aspect.

The expressions “ambient temperature” and “room temperature” as used herein are understood in the art and refer generally to a temperature from 20° C. to 35° C.

All disclosed values also include values that fall within ±10% variation from the disclosed value unless otherwise indicated or inferred. In other words, if a range of 1 to 10 is disclosed, then a range of about 1 to about 10 is disclosed. In such aspects, it is understood that the amount or value in question can be the exact value or a value that provides equivalent results or effects as recited in the claims or taught herein. That is, amounts, sizes, formulations, parameters, and other quantities and characteristics include both exact values but also approximate, larger or smaller values as desired, reflecting tolerances, conversion factors, rounding, measurement error, and the like, and other factors known to those of skill in the art such that equivalent results or effects are obtained. In some circumstances, the value that provides equivalent results or effects cannot be reasonably determined. In general, an amount, size, formulation, parameter, or other quantity or characteristic is “about,” “approximate,” or “at or about,” whether or not expressly stated to be such. Where “about,” “approximate,” or “at or about” is used before a quantitative value, the parameter also includes the specific quantitative value itself unless expressly stated otherwise.

As used herein, the term or phrase “effective,” “effective amount,” or “conditions effective to” refers to such amount or condition that is capable of performing the function or property for which an effective amount or condition is expressed. As will be pointed out below, the exact amount or particular condition required will vary from one aspect to another, depending on recognized variables such as the materials employed, and the processing conditions observed. Thus, it is not always possible to specify an exact “effective amount” or “condition effective to.” However, it should be understood that an appropriate, effective amount will be readily determined by one of ordinary skill in the art.

When a range is expressed, a further aspect includes from one particular value and to the other particular value. For example, where the stated range includes one or both of the limits, ranges excluding either or both of those included limits are also included in the disclosure, e.g., the phrase “x to y” includes the range from ‘x’ to ‘y’ as well as the range greater than ‘x’ and less than ‘y’. The range can also be expressed as an upper limit, e.g., ‘x, y, z, or less’ and should be interpreted to include the specific ranges of ‘x,’ ‘y,’ ‘z,’ ‘about x,’ ‘about y,’ and ‘about z’ as well as the ranges of ‘less than x,’ ‘less than y, or ‘less than z,’ or ‘less than about x,’ ‘less than about y, and ‘less than about z.’ Likewise, the phrase ‘x, y, z, or greater’ should be interpreted to include the specific ranges of ‘x,’ ‘y,’ ‘z,’ ‘about x,’ ‘about y,’ and ‘about z’ as well as the ranges of ‘greater than x,’ greater than y,′ ‘greater than z,’ or ‘greater than about x,’ greater than about y,′ ‘greater than about z.’ In addition, the phrase “‘x’ to ‘y’,” where ‘x’ and ‘y’ are numerical values, also includes “about ‘x’ to about ‘y’.”

Such a range format is used for convenience and brevity and, thus, should be interpreted flexibly to include not only the numerical values explicitly recited as the limits of the range but also to include all the individual numerical values or sub-ranges encompassed within that range as if each numerical value and sub-range is explicitly recited. To illustrate, a numerical range of “0.1% to 5%” should be interpreted to include not only the explicitly recited values of 0.1% to 5% but also include individual values (e.g., 1%, 2%, 3%, and 4%) and the sub-ranges (e.g., 0.5% to 1.1%; 5% to 2.4%; 0.5% to 3.2%, and 0.5% to 4.4%, and other possible sub-ranges) within the indicated range.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, a description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6 and any whole and partial increments therebetween. This applies regardless of the breadth of the range.

In still further aspects, when the specific values are disclosed between two end values, it is understood that these end values can also be included.

In still further aspects, when the range is given, and exemplary values are provided, it is understood that any ranges can be formed between any exemplary values within the broadest range. For example, if individual numbers 1, 2, 3, 4, 5, 6, 7, etc. are disclosed, then the ranges 1-7, 2-7, 3-7, 4-7, 5-7, 6-7, 1-6, 1-5, 1-4, 1-3, 1-2, 2-6, 2-5, etc. are also disclosed.

References in the specification and concluding claims to parts by weight of a particular element or component in a composition denote the weight relationship between the element or component and any other elements or components in the composition or article for which a part by weight is expressed. Thus, in a mixture containing 2 parts by weight of component X and 5 parts by weight, components Y, X, and Y are present at a weight ratio of 2:5 and are present in such a ratio regardless of whether additional components are contained in the mixture.

A weight percent (wt. %) of a component, unless specifically stated to the contrary, is based on the total weight of the formulation or composition in which the component is included.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

As used herein, the term “and/or” includes any and all combinations of one or more of the associated listed items.

It will be understood that although the terms “first,” “second,” etc., may be used herein to describe various elements, components, regions, layers, and/or sections. These elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example aspects.

As used herein, the term “substantially” means that the subsequently described event or circumstance completely occurs or that the subsequently described event or circumstance generally, typically, or approximately occurs.

Still further, the term “substantially” can, in some aspects, refer to at least 90%, at least 95%, at least 99%, or 100% of the stated property, component, composition, or other condition for which substantially is used to characterize or otherwise quantify an amount.

In other aspects, as used herein, the term “substantially free,” when used in the context of a composition or component of a composition that is substantially absent, is intended to refer to an amount that is then 1% by weight, e.g., less than 0.5% by weight, less than 0.1% by weight, less than 0.05% by weight, or less than 0.01% by weight of the stated material, based on the total weight of the composition.

As used herein, the terms “substantially identical reference composition,” “substantially identical reference article,” or “substantially identical reference electrochemical cell” refer to a reference composition, article, or device comprising substantially identical components in the absence of an inventive component. In another exemplary aspect, the term “substantially,” in, for example, the context “substantially identical reference composition,” or “substantially identical reference article,” or “substantially identical reference device,” refers to a reference composition, article, or a device comprising substantially identical components and wherein an inventive component is substituted with a common in the art component.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein are interpreted accordingly.

Terms such as “proximal,” “distal,” “radially outward,” “radially inward,” “outer,” “inner,” and “side” describe the orientation and/or location of portions of the components or elements within a consistent but arbitrary frame of reference which is made clear by reference to the text and the associated drawings describing the components or elements under discussion. Such terminology can include the words specifically mentioned above, derivatives thereof, and words of similar importance.

Some aspects described herein relate to methods. It should be understood that such methods can be computer-implemented. That is, where the method or other events are described herein, it should be understood that they may be performed by a computing device having a processor and a memory. Memory of a computing device is also referred to as a non-transitory computer-readable medium, which can include instructions or computer code for performing various computer-implemented operations. The computer-readable medium (or processor-readable medium) is non-transitory in the sense that it does not include transitory propagating signals per se (e.g., a propagating electromagnetic wave carrying information on a transmission medium such as space or a cable). The media and computer code (also referred to as code) may be those designed and constructed for a specific purpose or purpose. Examples of non-transitory computer-readable media include, but are not limited to magnetic storage media such as hard disks, floppy disks, and magnetic tape; optical storage media such as Compact Disc/Digital Video Discs (CD/DVDs), Compact Disc-Read Only Memories (CD-ROMs), and holographic devices; magneto-optical storage media such as optical disks; carrier wave signal processing modules, Read-Only Memory (ROM), Random-Access Memory (RAM) and/or the like. One or more processors can be communicatively coupled to the memory and operable to execute the code stored on the non-transitory processor-readable medium. Examples of processors include general purpose processors (e.g., CPUs), Graphical Processing Units, Field Programmable Gate Arrays (FPGAs), Application Specific Integrated Circuits (ASICs), Digital Signal Processor (DSPs), Programmable Logic Devices (PLDs), and the like. Examples of computer code include but are not limited to, micro-code or micro-instructions, machine instructions, such as those produced by a compiler, code used to produce a web service, and files containing higher-level instructions that are executed by a computer using an interpreter. For example, aspects may be implemented using imperative programming languages (e.g., C, Fortran, etc.), functional programming languages (Haskell, Erlang, etc.), logical programming languages (e.g., Prolog), object-oriented programming languages (e.g., Java, C++, etc.), or other suitable programming languages and/or development tools. Additional examples of computer code include, but are not limited to, control signals, encrypted code, and compressed code.

While aspects of the present invention can be described and claimed in a particular statutory class, such as the system statutory class, this is for convenience only, and one of ordinary skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred in any respect. This holds for any possible non-express basis for interpretation, including matters of logic with respect to the arrangement of steps or operational flow, plain meaning derived from grammatical organization or punctuation, or the number or type of aspects described in the specification.

The present invention may be understood more readily by reference to the following detailed description of various aspects of the invention and the examples included therein, and to the Figures and their previous and following description.

### Devices and Systems

This disclosure is directed to a device comprising a piezoelectric resonator and a micro- or nano-sized reservoir coupled to at least a portion of the piezoelectric resonator. In such aspects, the micro or nano-sized reservoir has a predetermined length and comprises a body having a predetermined volume and extending into a tip. In such aspects, the tip defines a distal portion of the reservoir and has a predetermined aperture diameter. In still further aspects, the predetermined length of the reservoir is measured from a coupling point to the piezoelectric resonator.

In still further aspects, the device can comprise one or more micro- or nano-sized reservoir(s). Yet in still further aspects, the two or more micro or nano-sized reservoirs can be positioned such that at least some or the portions of the each reservoir are fluidically coupled to each other. In still further aspects, the predetermined length is selected to provide a Q-factor of the piezoelectric resonator of 500 Hz to 10 kHz, including exemplary values of 550 Hz, 600 Hz, 650 Hz, 700 Hz, 750 Hz, 800 Hz, 850 Hz, 900 Hz, 950 Hz, 1 kHz, 1.5 kHz, 2 kHz, 2.5 kHz, 3 kHz, 3.5 kHz, 4 kHz, 4.5 KHz, 5 kHz, 5.5 kHz, 6 kHz, 6.5 kHz, 7 kHz, 7.5 kHz, 8 KHz, 8.5 kHz, 9 kHz, and 9.5 KHz. In still further aspects, the Q-factor can have any value between any two foregoing values. In yet still further aspects, the Q-factor can have any value that falls within a range formed by any two values described above. For example, the Q-factor can have a value of 500 Hz to 9 kHz, 500 Hz to 8 kHz, 500 Hz to 7 kHz, 500 Hz to 6 kHz, 500 Hz to 5 kHz, 500 Hz to 4 kHz, 500 Hz to 3 kHz, 500 Hz to 2 kHz, 500 Hz to 1 kHz, 500 Hz to 700 Hz, 600 Hz to 10 kHz, 700 Hz to 10 KHz, 800 Hz to 10 KHz, 900 Hz to 10 kHz, 1 KHz to 10 KHz, 2 kHz to 10 KHz, 3 kHz to 10 KHz, 4 kHz to 10 KHz, 5 kHz to 10 KHz, 6 kHz to 10 KHz and so on.

In yet still further aspects, the predetermined length can be 10 micrometers to less than 10 mm, including exemplary values of 20 micrometers, 50 micrometers, 75 micrometers, 100 micrometers, 125 micrometers, 150 micrometers, 175 micrometers, 200 micrometers, 250 micrometers, 300 micrometers, 350 micrometers, 400 micrometers, 450 micrometers, 500 micrometers, 550 micrometers, 600 micrometers, 650 micrometers, 700 micrometers, 750 micrometers, 800 micrometers, 850 micrometers, 900 micrometers, 950 micrometers, 1 mm, 2 mm, 3 mm, 4 mm, 5 mm, 6 mm, 7 mm, 8 mm, 9 mm, and 9.95 mm. In still further aspects, the predetermined length can have any value between any two foregoing values. In yet still further aspects, the predetermined length can have any value that falls within a range formed by any two values described above. For example, the predetermined length can have a value of 10 micrometers to 9.99 mm, 10 micrometers to 9 mm, 10 micrometers to 7 mm, 10 micrometers to 5 mm, 10 micrometers to 3 mm, 10 micrometers to 1 mm, 10 micrometers to 800 micrometers, 10 micrometers to 500 micrometers, 10 micrometers to 300 micrometers, 10 micrometers to 100 micrometers, 10 micrometers to 50 micrometers, 50 micrometers to 9.99 mm, 100 micrometers to 9.99 mm, 300 micrometers to 9.99 mm, 500 micrometers to 9.99 mm, 800 micrometers to 9.99 mm, 1 mm to 9.99 mm, 3 mm to 9.99 mm, 5 mm to 9.99 mm, and so on.

In some aspects, the body of the micro or nano-sized reservoir comprises (a) a first electrode; and (b) an electrolyte solution configured to at least partially disperse as a droplet from the tip on a surface of a substrate. In still further aspects, the first electrode can have any dimensions that would allow the desired application. In yet still further aspects, the first electrode can be a micro- or nanoelectrode.

In still further aspects, disclosed herein also a device comprising: a piezoelectric resonator; and a micro- or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter, wherein the predetermined length is measured from a coupling point to the piezoelectric resonator, wherein at least a portion of an interior portion of the body of the micro or nano-sized reservoir and/or at least a portion of an interior portion of the tip comprises a conductive material; wherein the body of the micro or nano-sized reservoir comprises an electrode; wherein the predetermined length is selected to provide a Q-factor of the piezoelectric resonator of 500 Hz to 10 KHz; a distance from the tip to the substrate surface is controlled by the piezoelectric resonator; and wherein the device is operated in a shear force mode, tapping mode, or a combination thereof.

In such exemplary and unlimiting aspects, the conductive material can comprise a metal, semiconductor, one or more conductive polymer layers, carbon-based materials, or any combination thereof. In yet still further aspects, the body of the micro- or nano-sized reservoir can comprise an electrolyte.

In certain aspects, the body is defined by one channel. Yet, in other aspects, the body can comprise two or more channels. In such aspects, where more than one channel is present, the first electrode can be positioned within one of the two or more channels.

In still further aspects, the device comprises a receptacle configured to receive the piezoelectric resonator and the micro- or nano-sized reservoir in the predetermined configuration.

In still further aspects, the device is a microscope probe providing a topographical mapping and redox activity of the substrate surface. In still further aspects, the device combines an atomic force probe and an electrochemical probe.

In still further aspects, the device can be used in the Scanning lon Conductance Microscopy. In such aspects, the micro- or nano-reservoir can be positioned under an electrolyte together with a reference electrode to probe the surface of a test sample by monitoring both force and ion conductivity.

In still further aspects, the distance from the tip to the substrate surface is controlled by the piezoelectric resonator. In certain aspects, the device can also comprise a stepper motor. In such aspects, the stepper motor can be used to control the distance from the tip to the substrate surface. Yet in still further aspects, the distance from the tip to the substrate surface is controlled by the piezoelectric resonator and by the stepper motor.

In certain aspects, the piezoelectric resonator is a tuning fork comprising two prongs. It is understood that the piezoelectric resonator can also comprise a stem (ground). In still further aspects, the fork is U-shaped.

In still further aspects, the micro- or nano-sized reservoir is coupled with one of the two prongs. In such exemplary and unlimiting aspects, the micro or nano-sized reservoir can be coupled to at least a portion of a distal end of the one of the two prongs with a fastener. It is understood that any known in the art fasteners can be used. For example, and without limitations, the fastener is an adhesive material. In yet still further aspects, the fastener is not an electrically conductive material. While in still further aspects, the coupling of the micro or nano-sized reservoir with the one of the two prongs can be assisted with a CCD camera using a mounting device disclosed herein.

The positioning of the micro- or nano-sized reservoir relative to the tuning fork can be adjusted to obtain the desired results. In certain aspects, the body of the micro- or nano-sized reservoir is substantially straight along a longitudinal axis perpendicular to the substrate surface. Yet, in other aspects, the body of the micro or nano-sized reservoir is substantially straight along a longitudinal axis perpendicular to a surface of the two prongs.

Yet in still further aspects, a portion of the body of the micro or nano-sized reservoir is bent along a transverse axis, forming a proximal bent portion and a distal straight portion, wherein the proximal bent portion of the body is substantially parallel to the substrate, and the distal straight portion extending into the tip is substantially perpendicular to the substrate. In still further exemplary aspects, the distal straight portion is in plane with a surface of the two prongs. In such exemplary and unlimiting aspects, the electrode is positioned within the proximal bent portion of the body.

In certain aspects, wherein at least a portion of the micro or nano-sized reservoir is vertically aligned with the prong surface while horizontally or vertically oscillating at a predetermined frequency above the substrate surface.

In still further aspects, the device can be used to investigate the electrochemical behavior of the sample. In such exemplary and unlimiting aspects, an electrochemical signal is collected at a tip-substrate surface contact point.

In certain aspects, the first electrode is a quasi-reference electrode. It is understood that the choice of the reference electrode depends on the type of a sample to be investigated, and the type of electrochemical behavior being studied. Any known in the art references to electrodes suitable for the desired application can be used. In still further aspects, the substrate is a working electrode. In certain aspects, a distal end of an outer surface of the nano-sized reservoir can be electrically conductive and behave as a counter electrode.

In still further aspects, where the electrolyte is present in the reservoir, such an electrolyte, can be chosen based on the desired application. It is understood that in certain aspects, the electrolyte comprises an aqueous solution of a salt. In still further aspects, the concentration of the electrolyte can be determined by the desired application. In certain aspects, the electrolyte can have a low concentration of the salt (0.01 M to 0.5 M, including all possible values that can be within this range), or it can have a high concentration of the salt (0.5 to 10 M, including all possible values that can be within this range). Yet in still further aspects, and if desired, the electrolyte can comprise an organic solvent and a salt. It is understood that the salt can be inorganic or organic, as long as it has a substantially dissociating in the solvent to provide an electrolyte solution. In certain aspects, the electrolyte can comprise a combination of organic and aqueous solutions. Yet in still further aspects, the electrolyte can be an ionic liquid.

It is understood that the droplet size and/or shape are defined by the aperture diameter of the tip, the hydrophobicity of the substrate surface, the electrowetting properties of the substrate surface, the vibration amplitude of the nano-sized reservoir, the predetermined length of the nano-sized reservoir, or a combination thereof. In certain aspects, the droplet has a size of 10 nm to 100 microns, including exemplary values of 50 nm, 100 nm, 200 nm, 300 nm, 400 nm, 500 nm, 600 nm, 700 nm, 800 nm, 900 nm, and 1 micron. 10 microns, 50 microns, 70 microns and 90 microns. In still further aspects, the droplet can have any value between any two foregoing values. In yet still further aspects, the droplet can have any size that falls within a range formed by any two values described above. For example, the droplet can have a size of 10 nm to 90 microns, 10 nm to 70 microns, 10 nm to 50 microns, 10 nm to 1 micron, 10 nm to 900 nm, 10 nm to 500 nm, 10 nm to 200 nm, 10 nm to 100 nm, 10 nm to 50 nm, 50 nm to 100 microns, 100 nm to 100 microns, 500 nm to 100 microns, 1 micron to 100 microns, 10 micrometers to 100 microns, 20 micrometers to 100 microns, 50 micrometers to 100 microns, 80 micrometers to 100 microns, and so on.

In still further aspects, the device is operated in a shear force mode, tapping mode, or a combination thereof.

In certain aspects, the device is configured to measure an electrical and/or electrochemical response and/or topography of the substrate surface with a spatial resolution from 10 nm to 100 microns, including exemplary values of 50 nm, 100 nm, 200 nm, 300 nm, 400 nm, 500 nm, 600 nm, 700 nm, 800 nm, 900 nm, 1 micron. 10 microns, 50 microns, 70 microns and 90 microns. In still further aspects, the spatial resolution can have any value between any two foregoing values. In yet still further aspects, the spatial resolution can have any value that falls within a range formed by any two values described above. For example, the spatial resolution can be 10 nm to 90 microns, 10 nm to 70 microns, 10 nm to 50 microns, 10 nm to 1 micron, 10 nm to 900 nm, 10 nm to 500 nm, 10 nm to 200 nm, 10 nm to 100 nm, 10 nm to 50 nm, 50 nm to 100 microns, 100 nm to 100 microns, 500 nm to 100 microns, 1 micron to 100 microns, 10 micrometers to 100 microns, 20 micrometers to 100 microns, 50 micrometers to 100 microns, 80 micrometers to 100 microns, and so on.

Also disclosed herein is a system comprising the disclosed above devices. In such aspects, the system can further comprise a substrate, wherein the substrate comprises a test sample and wherein the test sample is electrically conductive, insulating, semiconducting, or a combination thereof.

In still further aspects, the system further comprises a potentiostat. In yet other aspects, the system can comprise a DC/AC power supply, digital multimeters, source measure units, other testing units, or any combination thereof. In further aspects, the system comprises a light source, one or more cameras, a spectrometer, a photodetector, one or more microscope objectives, or a combination thereof. In yet still further aspects, the system further comprises a controlling unit.

The systems and devices disclosed herein provide photo- and electrochemical and topography sampling systems with micrometer and nanometer spatial resolution. In still further aspects, the systems and devices disclosed herein can be used to measure various properties of the sample, such as, for example, morphology, electrical signal, photocurrent, and corrosion. In yet still further aspects, the systems and devices disclosed herein can be used for the chemical and electrochemical patterning of the substrate. In still further aspects, the systems and devices disclosed herein can be used to study metal, semiconductor, and insulating materials. In still further aspects, the systems and devices disclosed herein can be used to resolve redox activities and correlations with the morphology of the sensor, energy materials, and photonic structure. In still further aspects, the systems and devices disclosed herein can be used to deliver the desired chemicals to any desired surface. Still further, the systems and devices disclosed herein can be used to quantify local liquid, solid, and gas entities and reactions. In still further aspects, the systems and devices disclosed herein can be used for chemical imaging and probing dual-channel signals of electrical and tuning fork frequency force.

Also disclosed herein is a mounting device comprising: a first portion configured to receive a QTF-AFM probe, wherein the AFM probe comprises a tuning fork comprising two prongs; a second portion configured to receive a micro or nano-sized reservoir; the first and the second portions are aligned with each other such that when the tuning fork is mounted within the first portion, and the micro or nano-sized reservoir is mounted within the second portion, the micro or nano-sized reservoir is positioned substantially vertically to a distal end of one of the two prongs of the tuning fork.

In certain aspects, the AFM probe further comprises a PCB control board controlling the tuning fork, wherein the first portion comprises a further portion configured to receive and mount the PCB control board.

In yet other aspects, the second portion comprises one or more orifices disposed at a predetermined distance from each other. In such exemplary aspects, the micro or nano-sized reservoir is configured to be mounted within one of the one or more orifices at a predetermined length relative to the tuning fork. In still further aspects, the second portion can also comprise one or more fasteners configured to immobilize the micro- or nano-sized reservoir within the orifice. It is understood that any known in the art fasteners can be used. For example, and without limitations, it can be special screws, clips, anchors, and the like.

It is understood that the positioning of the fork and the reservoir relative to each other and relative to other portions of the device of the system can be controlled by translation controllers. For example, the mounting device can further comprise one or more of x, y, z, xy, xz, yz, or xyz micro-positioning controllers configured to align the micro- or nano-sized reservoir with the prong of the fork. It is understood that x, y, and z directions can be chosen based on the conventional use of the coordinates and according to the movement of the tip.

In still further aspects, when the micro- or nano-sized reservoir is mounted in the second portion, and the tuning fork is mounted in the first portion, the micro- or nano-sized reservoir and tuning fork are coupled with an adhesive. The coupling with the adhesive can be done with the help of one or more CCD cameras or any other elements that can ensure a precise coupling position.

Also disclosed herein is a system comprising any of the disclosed mounting devices, further comprising one or more cameras, wherein the one or more cameras assist in mounting the micro- or nano-sized reservoir and tuning fork with the mounting device.

### Methods

Also disclosed herein are methods comprising: positioning a sample within the system comprising any of the disclosed above devices, measuring at least one property of the sample, wherein the at least one property is selected from the sample roughness, topography, electrical response, electrochemical response, photocurrent, or a combination thereof.

The methods can further comprise chemical and/or electrochemical patterning of a surface of the sample. While in other aspects, the methods can further comprise correlating a surface morphology of the sample with a local redox property of the sample.

In yet still further aspects, the method can further comprise transporting a predetermined material to the sample. Yet in still further aspects, the method can further comprise quantifying local reactions on the sample. Yet in still further aspects, the method can further comprise chemical imaging of the sample.

Also disclosed herein are methods of forming a micro or nano-sized reservoir. In such aspects, these methods can comprise pulling a capillary tube to obtain a micro or nanopipette having a body and a tip, wherein the tip is defined by a predetermined aperture diameter and the body has a predetermined length; filling the body of the micro or nanopipette with an electrolyte solution such that the tip is substantially free of air bubbles. In certain aspects, the capillary pulling can be CO₂-assisted.

The predetermined length can be any length disclosed above.

In still further aspects, the step of filling can be thermally driven. In certain aspects, the step of filling can comprise filling the micro or nanopipette from an opening opposite to the tip with water; heating the nanopipette at a temperature of room temperature to 100° C. (including any temperature values that can fall within the range, for example, 25° C. to 100° C., 30° C. to 80° C., 50° C. to 100° C., and so on) to create a thermal gradient, and replacing water with an electrolyte solution.

To ensure that the electrolyte is not evaporated or lost by any other means, the filled nanopipette can be kept in a solution bath comprising the electrolyte solution.

Also disclosed herein are methods of positioning and coupling a tuning fork and a micro or nano-sized reservoir in the disclosed herein mounting devices. In such aspects, the coupling can be monitored by a dual-camera system. Yet in other aspects, the coupling can comprise adhering a portion of the micro- or nano-sized reservoir to a prong of the tuning fork. In yet still further aspects, the method can further comprise vertically aligning positioning of at least a portion of the micro or nano-sized reservoir relative to the tuning fork.

In aspects, where the outer or interior portions of the reservoir comprise a conductive material, such material can be deposited by any known in the art methods. For example, they can be deposited by electroless deposition, CVD, PECVD, ALD, electrodeposition, metal sputtering, vapor deposition, any combination thereof, and so on.

Also disclosed herein is a method of using any of the disclosed herein devices of systems. In certain aspects, disclosed is a method comprising: obtaining an AF morphology image of a sample at open circuit potential, wherein the image comprises one or more regions of interest (ROIs); moving any of the disclosed herein devices to the one or more regions of interest; performing a cycling voltammetry at the one or more regions of interest to probe a local redox activity. In such exemplary and unlimiting aspects, the step of collecting is performed while a droplet size is substantially without a change.

Still further disclosed herein is a method comprising positioning a sample in any of the disclosed above systems and measuring the local redox activity of the sample by any of the disclosed above devices.

The claims are not intended to include and should not be interpreted to include means-plus- or step-plus-function limitations unless such a limitation is explicitly recited in a given claim using the phrase(s) “means for” or “step for,” respectively.

In view of the described processes and compositions described below are described certain more particularly described aspects of the inventions. These particularly recited aspects should not, however, be interpreted to have any limiting effect on any different claims containing different or more general teachings described herein or that the “particular” aspects are somehow limited in some way other than the inherent meanings of the language and formulas literally used therein.

### EXAMPLES

The following examples are put forth so as to provide those of ordinary skill in the art with a complete disclosure and description of how the compounds, compositions, articles, devices, and/or methods claimed herein are made and evaluated and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is degrees C. or is at ambient temperature, and pressure is at or near atmospheric.

### Experimental Methods

### Silver Nanowire Synthesis

The Ag nanowire was synthesized using the polyol reduction method. Initially, 5 m ethylene glycol was heated to 160° C. under continuous stirring in a glass vial immersed in an oil bath. Then, 40 μL of 4 mM CuCl₂. H₂O/ethylene glycol was added to the heated solution and heated for 15 minutes. An ethylene glycol solution containing 1.5 mL of 114 mM (monomer concentration) polyvinylpyrrolidone (PVP) in ethylene glycol and 1.5 mL of 94 mM AgNO₃ was added to the solution, and the stirring was stopped after 10 minutes. The reaction was allowed to continue for another 1 hour until the solution became gray and wispy. The Ag NWs were then collected by centrifugation, rinsed with acetone, and stored in isopropanol.

### AgNWs@ITO Fabrication

Ag NWs were deposited on precleaned ITO by drop casting and spray-coating. Before depositing AgNWs, the ITO substrate was thoroughly cleaned by sonicating with deionized water, soap, and acetone for 10 minutes. 20 μL of the as-prepared Ag NWs in isopropanol was then dropped cast on the ITO surface and dried in air and at room temperature. The spray coating was carried out with an airbrush system connected to Argon gas to provide an inert atmosphere and reduce oxidation during coating. The precleaned ITO was set on a hot plate and heated to 50° C. The isopropanol containing the Ag NWs was loaded in an airbrush, and the suspension was evenly applied to the hot ITO to achieve a uniform Ag NWs layer. The prepared samples were thoroughly cleaned with DI water to remove unattached Ag NW.

### Multilayer MoS₂ Film

Thin natural MoS₂ crystals are deposited on a precleaned ITO substrate using mechanical exfoliation using the scotch tap method. Mechanical exfoliation is the most efficient way to produce a pristine, highly crystalline, and thin layer of MoS₂ from the bulk crystal. A multilayer layer (ML) of MoS₂ crystal is transferred onto a precleaned ITO surface using the adhesive scotch tap method. A piece of the scotch tape is gently pushed down to the MoS₂ crystal surface to make good contact with the crystal. Then, the tap is peeled off from the crystal surface to remove a layer of MoS₂ from the bulk crystal. The freshly cleaved MoS₂ crystals are pressed on the precleaned ITO substrate and rubbed with a plastic tweezer to transfer the MoS₂ crystal layer to the substrate. The tap is carefully removed from the substrate surface, leaving a thin layer of MoS₂ behind. The prepared sample is then thoroughly washed with deionized water and acetone to remove scotch tap adhesive and unattached MoS₂.

### Nanotip Fabrication

The nanopipettes with 30 nm diameter were fabricated using a CO₂-assisted pipette pulling system (Shutter Instruments, P-2000) from a quartz capillary tube of 1 mm outer diameter and 0.7 mm inner diameter directly purchased from Shutter Instrument. The CO2-assisted pipette-pulling system has several benefits over other pipette-pulling systems, as it quickly fabricates nanometer-sized pipettes without leaving any filament residue. The aperture size of the nanopipette can be controlled easily by changing pulling parameters.

A thermally driven approach was adopted to fill the nanopore with electrolytes and make good electrical contacts. Briefly, deionized (DI) water is introduced into the nanopipette through its rear opening using a long syringe. The nanopipette is placed on a hot plate at 80° C. for two hours to create a thermal gradient along the nanocapillary. This facilitates the diffusion of DI vapor into the nanopore and ensures that the nanopore is filled as water vapor condenses. Subsequently, the DI water is carefully replaced with 10 mM H₂SO₄. Then, electrolyte-filled nanopipettes are immersed in a solution bath containing 10 mM H₂SO₄ to restrict electrolyte evaporation and long-term storage.

An I-V curve measurement for the nanopipettes is performed in a 10 mM H₂SO₄ solution before attaching the nanopipette to the tuning fork to verify electrical contact and confirm the nanopore's filling (FIGS. 4A-4B). In the I-V curve, the asymmetric current response during forward and backward scanning indicates effective electrical contact, increasing the ion transport current as the nanopipette aperture diameter widens. An asymmetric ion transport current can be attributed to the dominance of cations (H⁺) as charge carriers. This asymmetry results from the flux of cations through the nanopore and the hysteresis charge, with the cations acting as counterions to the negatively charged nanoconfined pipette surface. No current response was observed when the nanopore was not filled with electrolytes, and the electrical circuit was not completed.

### Nanopipette Attachment System

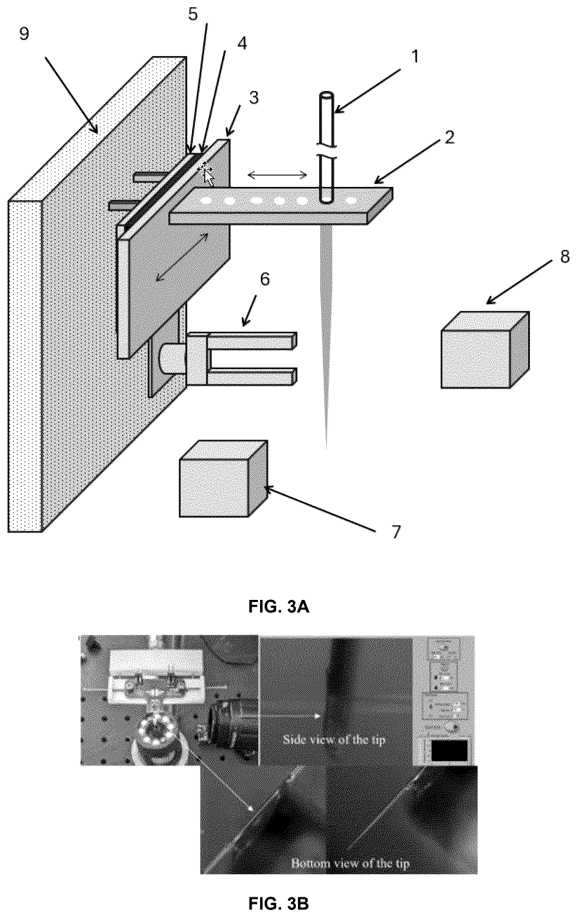

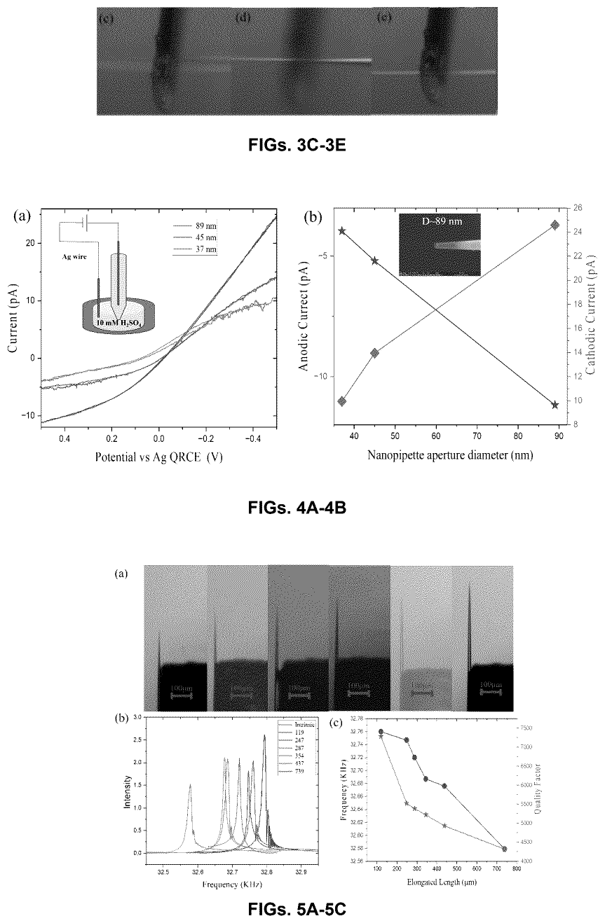

The nanopipette was securely attached to a tuning fork prong under dual camera surveillance using a mounting device disclosed herein and shown in FIGS. 3A-3E.

The mounting device is schematically shown in FIG. 3A. The first portion of the mounting device 3 is configured to receive an atomic-force microscope (AFM) probe marked as 4 and 5. The AFM probe comprises a tuning fork 6 comprising two prongs and a PCB control board 5 that controls the operation of the tuning fork 6. The mounting device further comprises a second portion 2 configured to receive a micro or nano-sized reservoir, such as a micro or nano pipette 1. The mounting device further comprises one or more of x, y, z, xy, xz, yz, or xyz micro-positioning controllers configured to align the micro- or nano-sized reservoir with the prong of the fork that is schematically shown as a translation stage 4 that can be controlled by the disclosed above micro-positioning controllers.

The mounting device can also be mounted on a mounting board support 9.

In certain aspects, the translation stage permits controlled x-directional movement of the commercial AFM probe holder with two precision screws attached to it. The stage microcontroller ensures precise distance control between the tuning fork prong and nanopipette tip, minimizing the risk of breaking the tip apex during attachment. The elongated length of the nanopipette apex (length from the glue attachment point to the tip apex) and the attachment angle are monitored using a dual-camera system, as schematically shown as 7 and 8. The tip attachment process involves several key steps, as depicted in FIG. 3C-3D: Initially, the commercial probe holder with the tuning fork is moved to a secure distance using the screw of the micro translation stage, and the nanopipette is carefully attached to the holder. The side camera is focused on the tuning fork to apply glue to one prong. Then, the camera is focused on the nanopipette, and the AFM probe is moved toward the pipette carefully with micro-distance control until contact is made. Following that, the rear camera is positioned to check the angle between the prong and the tip using a 3-dimensional translational stage and adjust the angle between the prong and the tip to ensure the nanopipette's vertical alignment. Finally, the system is allowed to rest for 15 minutes to let the glue dry completely before proceeding with further experiments.

### TF-SECCM Configuration

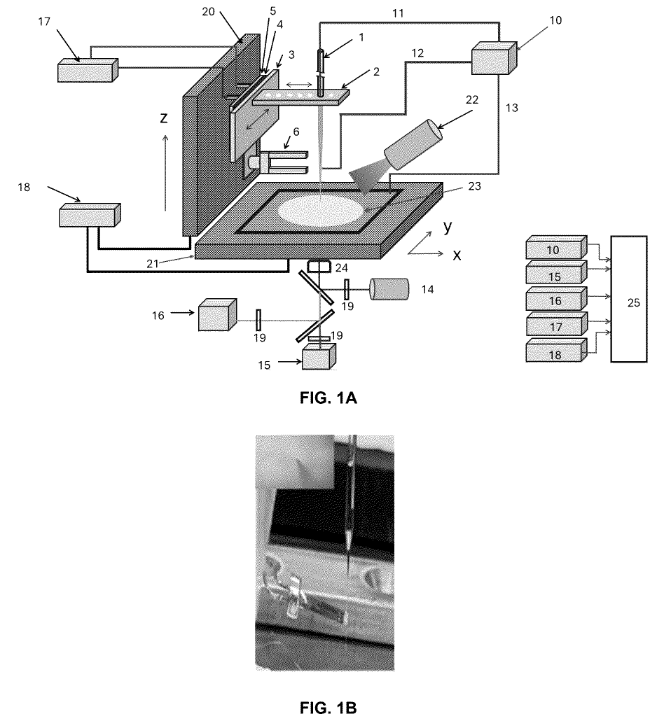

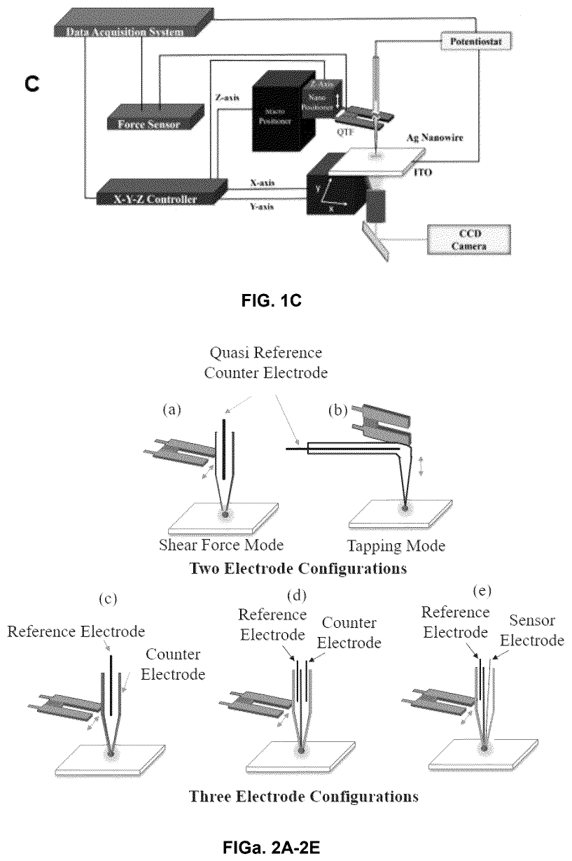

The schematic diagram of a system using the devices disclosed herein is shown in FIG. 1A.

The system can comprise, for example, a micro or nano-sized reservoir (such as nanopipette 1) filled with a liquid electrolyte and positioned within a second portion 2 of the disclosed above mounting device. The first portion 3 of the mounting device is configured to hold the AFM probe (for example, PCT board 5 and tuning fork 6). Tuning fork 6 positioning relative to the nanopipette can be adjusted as needed. The actual positioning of the AFM probe relative to the nanopipette is controlled by x, y, z,-microcontrollers (schematically shown as 4). The system can further comprise a vertical (z) positioning 20 and an additional x and y positioner 21. In certain aspects, the system can also comprise a light source 22, such as a laser, LED, or any other light source that can be used for photoexcitation of the sample if desired. The electrochemical sensing is performed by using the potentiostat 10. The reference electrode 11 is positioned within the reservoir 1. As disclosed herein, in certain aspects, the reservoir can have two or more channels. In such aspects, for example, the reference can be positioned within one of the channels. In certain aspects, when needed, the system can also comprise a counter electrode 12. In such aspects, for example, and without limitations, an outer portion of a distal end of the reservoir can be coated with a conductive layer to form the counter electrode 12. The system further comprises a substrate 13 that works as a working electrode. The same 23 is positioned on the substrate.

In certain aspects, an additional source of light 14 can be positioned under the sample to allow for sample illumination and/or excitation if desired. The system can further incorporate at least one CCD camera 15 and spectrometer 16 (or photodetector) if needed.

The system further comprises a control system such as, for example, a tuning fork sensor/controller 17 and an x, y, and z positioner driver 18. In certain aspects, if needed, the system can also comprise filters for wavelength rejection/selection 19 and microscope objective 24.

The potentiostat 10, CCD camera 15, spectrometer 16, tuning fork controller 17, and positioner drive 18 are further controlled by a processor 25. \

FIG. 1C shows another aspects of a similar setup. A nanopipette filled with electrolytes and attached to one prong of the QTF functions as the system's probe for topography mapping. The pipette tip approach to the surface with precise distance guidance of the QTF prevents tip damage when landing on a hard surface. A function generator attached to the system drives the QTF at its resonance frequency and fine-tunes the oscillation by adjusting the driving force. An X-Y directional piezo-position controller enables accurate raster scanning of the surface during topographical mapping and precise tip positioning at the targeted area of interest. A Charge-Coupled Device (CCD) camera is positioned under the transparent sample to monitor the nanopipette's approach to the substrate in real-time and to facilitate optical inspection of the specimen. This setup is essential for precisely positioning the nanopipette tip over specific targeted silver nanowires (Ag NW) on the sample's surface. The system utilizes a sample scanning configuration in which the pipette attached to the QTF is mounted in the Z piezo axis, allowing it to move only on the z-axis, and the sample is mounted on a two (x-y) piezo positioner for lateral movement. The electrolyte within the pipet forms a tiny electrochemical cell at the tip-surface contact point and facilitates electrochemical measurement of the targeted point of interest. A two-electrode system is used for potential scanning of the sample where Ag NW coated ITO substrate is the working electrode, and the Ag wire inserted in the pipet from the back orifice is the queasy reference counter electrode (QRCE).

FIGS. 2A-2E show various operating conditions of the disclosed system. When desired, the described system can operate in shear force mode (FIG. 2A) or tapping mode (FIG. 2B). In other aspects, and as disclosed herein, the system can comprise a reference electrode positioned within the reservoir and counter electrode positioned on the outer surface of the distal end of the reservoir (FIG. 2C). Yet in still further aspects, the reference and counter electrodes can be positioned in separate channels but when the channels are at least partially fluidically connected (FIG. 2D). In still further aspects, the system can comprise a sensor electrode configured to sense a specific property as desired (FIG. 2E). In such exemplary aspects, for example, the electrodes when positioned in two or more reservoirs communicate electrochemically to provide feedback upon the tip landing on a surface. These two electrodes can serve as a counter and reference electrode for accurate potential and current control and measurement. In another example and as disclosed above, one of the two liquid reservoirs can also be replaced with a Pt wire nanoelectrode to be in contact with the liquid reservoirs (FIG. 2e) so it can be used to electrochemically detect chemical species from the sample surface.

The tuning fork used herein is a Quart Tuning Fork that is a susceptible force sensor adaptable to ambient experimental conditions, leveraging its piezoelectric properties and mechanical resonance. Using a tuning fork over the traditional cantilever-based tip holder has several benefits when collecting topographic images using the nanopipette/nanorods. Firstly, due to the large size of the pipette, traditional cantilever-based tip holders are unsuitable for holding the pipette tip. In contrast, a tuning fork can easily accommodate it. Secondly, the QTF can prevent the “jump-to-contact” issue, a frequent problem in conventional cantilever-based systems where the tip suddenly snaps to the scanned surface. Finally, a cantilever-based AFM system requires an expensive optical positioning system and meticulous tip fabrication for collecting local electrochemical signals, making it a costly option. The disclosed setup allows precise positioning of the nanopipette tip over specific targeted Ag NW) on the sample's surface. The shear force mode is employed to reach the sample surface. In the shear force mode, the apex of the nanopipette, vertically aligned to the tuning fork prong, oscillates at a certain frequency horizontally near the sample surface. The approach of the tip at the sample surface can be accurately measured from the frequency damping caused by the interatomic force as the tip comes close to the surface. A micron-sized electrochemical cell is formed at the tip-sample contact point to enable the collecting of local surface electrochemical signals. The Ag NW under investigation is several micrometers long and 100-130 nm in diameter. It can be easily visualized through the CCD camera, utilizing white-light illumination due to its strong visible-light scattering and absorption. The electrochemical cell setup consists of a two-electrode system, an ITO substrate coated with Ag NWs as the working electrode, and an Ag wire inside the nanopipette functioning as the Quasi Reference Counter Electrode (QRCE). The size of the droplet forms at the tip-sample interface is influenced by the nanopipette aperture's diameter, the sample's hydrophilic nature, and the vibration amplitude at the nanopipette apex. Due to the hydrophilic nature of the ITO surface and the lateral vibrational amplitude, a micrometer-sized droplet is formed at the tip-surface contact. The rupture of the droplet and liquid dispersion can occur at extreme electrical potential bias, likely due to the formation of gas bubbles (H₂). The laboratory setup is built on a commercial AFM setup (Mad City Labs).

FIG. 1B shows a photograph of the positioning of the nanopipette relative to the tuning fork.

### Example 1

A systematic analysis of the QTF resonance frequency and quality factor (Q-factor) response with the tip apex length from the QTF prong contact point is shown in FIGS. 5A-5C. The resonance frequency and the quality factor decrease with the increase of the elongation of the tip apex. In particular, a drastic reduction in resonance frequency was observed when the attachment length of the nanopipette exceeded 500 micrometers. A short attachment length causes low degradation of the Q-factor, whereas a long one significantly reduces the Q-factor due to the increased center of mass. Q-factor is a dimensionless parameter that indicates the level of underdamping of an oscillator or resonator. It characterizes a system's damping relative to its resonant frequency, Q=Resonant Frequency/Bandwidth. A high Q-factor is desirable for AFM applications because it enables more sensitive and precise measurements. We maintain a length of the tip apex from the attachment point within a range of 200 to 300 micrometers to achieve a Q-factor of 6000, which provides enough sensitivity for surface investigation. Additionally, an increase in the apex length from the attachment point led to the formation of a dumbbell-shaped liquid meniscus at the tip-substrate contact point, which can be attributed to the increased lateral vibrational amplitude at the tip apex in one axis with a high elongated length.

Ag NP and Ag NW electrodes have catalytic properties for hydrogen peroxide reduction, show enhanced Raman scattering at the cross-linked and the bundle of Ag NWs, and present strong photoluminescence at a single Ag NWs. These spectro-electrochemical signals are used to study the heterogeneity of the redox properties of Ag NP and NW, which are not visible in the bulk ensemble measurement.

In this example, the QT-SECCM approach for directly measuring the local surface electrochemistry of single Ag nanowires is introduced. Electrochemical analyses at single Ag NWs, at intersections of multiple Ag NWs, and the ITO substrate were performed to investigate the local electrochemical activity of Ag oxidation-reduction, ITO surface degradation, and hydrogen evolution reactions. The intersection of multiple Ag NWs is found to have strong catalytic activity towards HER compared to that of single Ag NW and ITO substrates. The redox peak positions of Ag oxidation-reduction at individual Ag nanowires were observed to vary, indicating variation in surface electrochemistry among nanowires.

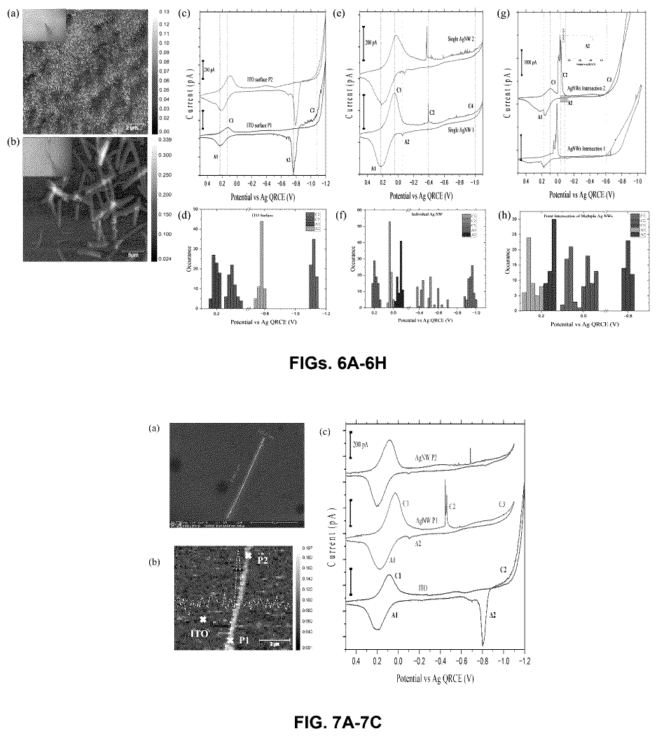

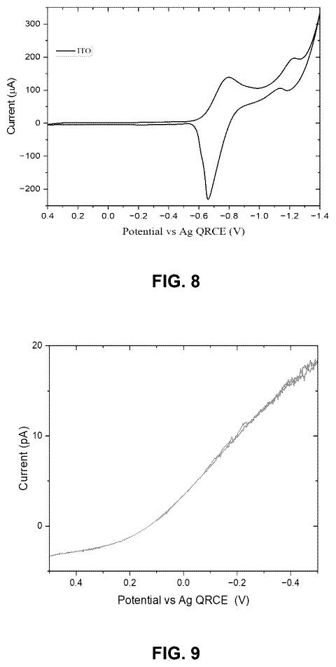

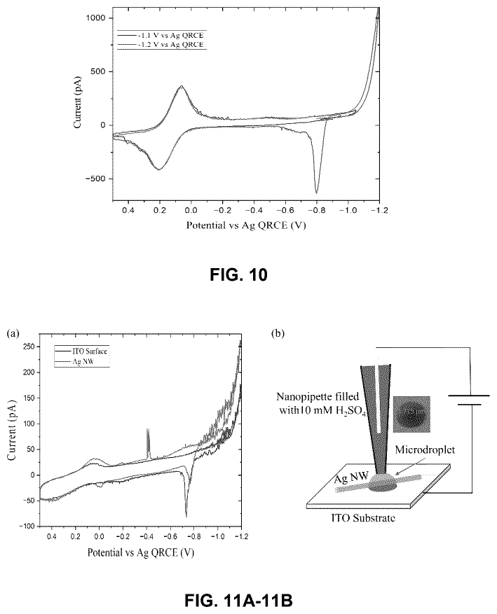

ITO substrate was chosen for this study due to its high electrical conductivity and optical transparency. ITO is commonly considered an inert substrate. However, irreversible surface degradation is observed during potential scanning and is influenced by various factors, including electrode conductivity, pH levels, electrolyte composition, the In:Sn ratio, and surface properties. Thus, the ITO surface's chemical stability and redox activity are of great interest in determining its application as supporting materials for its various applications, including electrodeposition. A thin layer of In₂O₃ and SnO₂ is sputter-coated on a glass substrate for ITO fabrication. The surface features a complex, non-stoichiometric microstructure (FIG. 6A). The intrinsic conductivity at the surface can differ significantly due to the local variations in the In:Sn ratio and surface defects, such as oxygen vacancies and grain structures. The cyclic voltammogram collected at different point locations at the same ITO surface showed notable catalytic heterogeneity. All the CVs at the ITO show characteristic features with four distinct redox peaks (FIG. 6C), indicating electrochemical processes unique to this substrate. A quasi-reversible system consistently appeared across all cyclic voltammograms (CVs) taken at the ITO surface, characterized by two bell-shaped peaks with equal charge (C1 and A1, respectively), which can be attributed to sulfate ions (SO₄²⁻) adsorption and desorption on the ITO surface, as supported by previous reports. This redox peak is absent in bulk CV measurements of ITO with the same electrolyte, suggesting a surface-specific interaction (FIG. 8). Additionally, a control experiment confirms that ion transport limitations through the nanopore during potential bias (FIG. 9) do not cause this redox peak. The electrochemical reduction occurs at the high negative polarization with an onset potential of −1.12 (designated as C2), which is the reduction of Sn⁴⁺ and In³⁺ to a lower oxidation state or metallic phase accompanied by HER. The reduced ITO can undergo complete or partial oxidation in the subsequent forward polarization, as revealed by the characteristic double oxidation peak at −0.8 V (A2). This oxidation peak does not appear in the consecutive forward polarization if the potential is not negative enough to reduce ITO into metallic NPs (FIG. 10). Furthermore, an electrochemical phase formation is reconfirmed by a crossover in the CV response around −0.86 V. This transformation is likely due to the reduction of electrode materials (In and Sn) to metallic nanoparticles (In NPs) or species in a lower oxidation state. Additionally, the variability in the peak potential at different points on the ITO surface underscores the electrochemical heterogeneity of the ITO surface (FIG. 6D). Such heterogeneity has been documented in prior studies, reinforcing the intricate interplay between the physical properties of the material and its electrochemical behavior.

Topographical mapping of the Ag NWs deposited on the ITO surface shows the presence of individual and bundle Ag NWs at the surface (FIG. 6B). The Ag NWs have a length of several micrometers with 100-130 nm diameter. Individual Ag NWs show distinct CV characteristic features than those taken at the ITO surface (FIG. 6E). CVs taken at ITO and Ag NW with extended negative polarization potential show the ITO oxidation peak and the adsorption-desorption peak for SO₄²⁻ ions with an additional redox peak when particularly taken on Ag NW (FIGS. 11A-11B). The quasi-reversible redox peaks previously attributed to SO₄²⁻ ion adsorption-desorption, designated as C1 and A1, are present in the CVs taken at the individual Ag NW. This can be explained by the ITO surface being partially exposed to the droplet formed at the tip-surface contact point due to the hydrophilic nature of the ITO surface. The new pair of redox peaks are generated from the oxidation and reduction reaction that occurs at the Ag NW. The small oxidation peak observed at −0.05 V versus Ag QRCE, denoted A2, is assigned to the Ag oxidation to Ag⁺. Ag can oxidize to Ag₂O or Ag₂SO₄; however, the formation of Ag₂O is commonly observed in alkaline medium. Ag is more likely oxidized to form Ag₂SO₄ in the present condition due to SO₄²⁻ ions in the solution. Ag⁺ can be further oxidized to unstable Ag(II), but the oxidation peak is obscured by the SO₄²⁻ desorption peak.

A sharp reduction peak at approximately −0.4 V (C2) shows rapid Ag reduction in the subsequent backward scan (FIG. 6E). When the potential is scanned to a more negative potential direction, a steady-state reduction current is observed starting at −0.5 V due to the reduction of dissolved O₂ that was previously reported to occur at −0.3 V vs Ag/AgCl in a three-electrode system in alkaline medium. A sharp increase of the reduction current at −1.0 V shows the proton reduction at the Ag surface. The onset potential for HER at single Ag NW shifts around 100 mV in a positive direction, confirming efficient HER at the Ag surface compared to the ITO. CVs taken at various Ag NWs also exhibit variations of peak potential locations, indicating redox heterogeneity in the NW population (FIG. 6F). A narrow peak potential distribution range for Ag oxidation (A2) is due to the straightforward Ag oxidation to stable Ag⁺. However, the broad range of peak potentials observed for Ag reduction on various Ag NW surfaces may be attributed to differences in the amount of surfactant molecules adsorbed during nanowire synthesis, as well as variations in intrinsic electrical conductivity due to the loose attachment at the ITO surface, which is a subject of further study.

Electrochemical measurement performed at the Ag NW bundle showed a distinct CV feature compared to the single Ag NW and ITO surface, with higher catalytic activity towards HER and a low overpotential and high reduction current response (FIG. 6G).

The higher catalytic activity of the Ag NW bundle can be attributed to a high surface area with more catalytically active sites and easy electron mobility through the NW network. An oxidation peak denoted to A2 is also prominent in CVs taken at the Ag NW bundle intersection, indicating passivating Ag₂SO₄ film formation at the Ag surface. Interestingly, the current after the A2 does not drop to zero as observed at the single Ag NW surface but shows a plateau due to the slow Ag₂SO₄ film formation on a larger surface. The sharp oxidation peak followed by this plateau (denoted by A1) can be assigned to Ag⁺ oxidation to Ag²⁺ by AgO formation following the Ag transformation route Ag→Ag₂SO₄→AgO. Moreover, the SO₄²⁻ adsorption-desorption peak shape at the Ag NW bundle differs from that observed at the ITO surface, indicating surface reaction bound to the Ag NWs bundle surface.

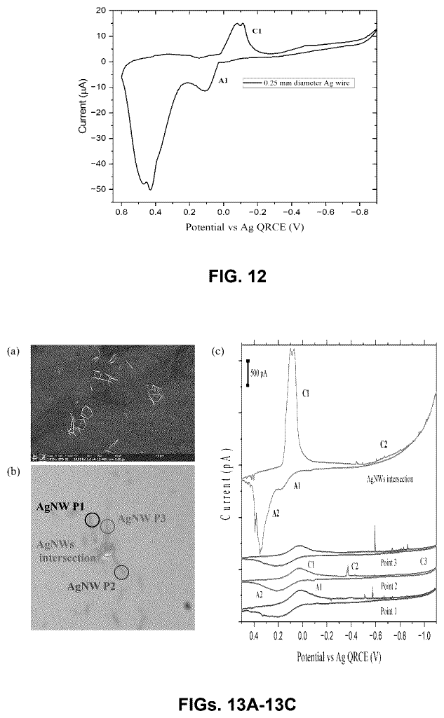

A sharp reduction peak, denoted by C2, during the backward scanning, is assigned to the reduction of oxidized Ag. Multiple satellite peaks in C2 indicate a complex reduction process contributed by multiple Ag NWs exposed to the electrolyte. Moreover, the reduction peak shifted to approximately 400 mV in the positive direction due to the facile reduction at the Ag NW bundle. More interestingly, the CV is similar to the CV taken on an Ag wire with a diameter of 0.25 mm in a 10 mM H₂SO₄ bulk solution (FIG. 12). This observation indicates that individual nanostructures exhibit distinct electrochemical activities compared to bulk materials. The hydrogen evolution reaction (HER) is initiated at the Ag NW bundle, characterized by a low onset potential of −0.63 V vs. Ag QRCE, along with a pronounced increase in the current response. The enhanced catalytic activity at the NWs crossover points is likely due to the increased electroactive surface area compared to a single Ag NW. This larger surface area, coupled with the interconnected network of nanowires, provides additional active sites for the reduction process. Furthermore, the aggregation of Ag NWs at these intersections may alter the local electrochemical conditions.

The variability in redox activity along a single Ag NW becomes apparent through the collection of cyclic voltammograms (CVs) at both ends of the nanowire. The SEM micrograph details the dimensions of a single Ag NW (FIG. 7A), while the topographical image illustrates the surface roughness (FIG. 7B). The CV recorded at the ITO demonstrates the adsorption and desorption of SO₄²⁻ ions, an In/Sn redox peak, and the HER. The CVs obtained from the Ag NW show an additional peak for Ag oxidation-reduction. The notable differences in the location of the Ag reduction peak potentials indicate variations in surface electroactivity and the presence of adsorbed molecules along the nanowire's length.

In summary, the local electrochemical behavior of single Ag NW, Ag NW bundle, and substrate materials employing the novel SECCM approach coupling nanopipette to a tuning fork for a force-guided surface approach of the tip was investigated. It was revealed the following: 1. crossover of multiple AgNWs is catalytically more active and facilitates HER than a single Ag NW and ITO surface due to high catalytically active surface area and easy electron mobility along the nanowire network; 2. Ag oxidation and reduction redox peak potential at a single Ag NW surface significantly differ from the nanowire bundle. Indeed, the Ag redox peak position at the nanowire bundle is comparable to the bulk Ag wire, and 3. heterogeneity in redox activity across the nanowire population and ITO surface. TF-SECCM approach presented here can rapidly obtain morphological and fast electrochemical information to explore complex electrochemistry at the targeted region of interest. The study also suggests that the droplet size formed at the tip-surface contact depends not only on the nanopore diameter but also on the hydrophilic character of the sample surface, tip elongation, and humidity. Future replacement of aqueous electrolytes with ionic or solid-state electrolytes and chemical modification of the sample surface to make it more hydrophobic might address this challenge. Additionally, the introduction of tapping mode surface scanning can improve the resolution of topographic imaging and will reduce electrolyte dispersion.

FIG. 13A depicts an SEM image of the individual and Ag NWs bundle at the ITO substrate. FIG. 14B shows a CCD camera image of the CV collection points at a single Ag NW and the intersection of multiple Ag NWs. FIG. 13C shows CVs of various point locations indicated in the image (FIG. 13B) with 10 mM H₂SO₄ by using nanopipette-based QTF-AFM. The scan rate was 30 mV/s.

### Example 2

### Local Electrocatalytic Heterogeneity at Natural MoS₂ Crystal

The natural MoS₂ thin layer has been investigated using the TF-SECCM technique as a model system to elucidate the relationship between surface electrocatalytic reactivity and structure. It has been previously reported that the basal plane of 2H MoS₂ exhibits either catalytic inertness or significantly low catalytic activity towards the hydrogen evolution reaction (HER), attributable to its surface structure, semiconducting properties, hydrophobic nature, scarcity of H adsorption sites, and high hydrogen adsorption energy. In contrast, HER activity is significantly enhanced at the surface defect sites, including edges, steps, crevices, and sulfur vacancies. Nanostructure engineering, including surface modification to create sulfur vacancies, metal-nonmetal doping, and electrochemical pretreatment of MoS₂ films, is widely used to enhance catalytic activity. The thin or monolayer form of MoS₂ is a highly studied material for electrochemical HER for its enhanced surface area, conductivity, and high catalytic activity. Various highly sensitive methods have been adopted to create a thin/monolayer of MoS₂, including hydrothermal process, chemical vapor deposition, wet synthesis, electrodeposition, and mechanical and electrochemical exfoliation. However, there are few studies on bulk or thin MoS₂, although the crystal structure of natural MoS₂ has fewer defects. This is primarily because of the bulk MoS₂ crystal's low catalytic activity. Additionally, the ensemble averaging electroanalytical methods previously used for pristine MoS₂ analysis provide the cumulative catalytic activity of the surface.

Herein, multilayer MoS₂ (approximately 200-300 nm) is studied using the TF-SECCM approach to reveal its redox activity and structural morphology at different regions. The investigation of the thin film pristine MoS₂ shows that: 1. defect sites of the MoS₂ are catalytically more active compared to the basal plan sites, 2. electrochemical oxidation enhances the catalytic activity of the film, and 3. The electrocatalytic activity of MoS₂ varies at distinct point locations, including diverse edge sites and MoS₂ flakes.

FIG. 14A shows the 2D topographic image of the isolated MoS₂ thin film at the ITO substrate. The investigated MoS₂ is approximately 200 nm thick, exhibited by line profile 4 (FIG. 14C), consisting of approximately 250 monolayers (each MoS₂ layer is 0.68 nm). The line profiles of the MoS₂ clearly show the presence of edge (lines 1 and 2) and basal plane (line 3). The SEM image confirms the presence of these features at the MoS₂ (FIG. 14B). Cyclic voltammetry was systematically performed at designated points of interest to investigate the redox behavior after topographical imaging. A high catalytic activity is observed at the edge site of the MoS₂ (Point 2) compared to the basal plane (Point 3). The backward scan reveals two reduction peaks, C1 and C2, attributed to the reduction surface Mo(VI) to Mo(IV) and Mo(IV) to Mo(III)/Mo(II), respectively.

The source of Mo(VI) at the MoS₂ edge can be explained by the previous observation of the formation of a thin MoOs film on MoS₂, even under atmospheric conditions, due to surface oxidation by water vapor at room temperature in humid environments. This redox activity is further discussed in the later part of this chapter. The onset potential for HER reaction at the edge sites shifted positively, indicating higher catalytic activity at the edge than at the basal plane sites. An oxidation peak in the cyclic voltammetry (CV) taken at the edge site is also observed at −0.1 V, denoted by A1, and can be assigned to Mo(III)/Mo(II) oxidation to Mo(IV). However, the cyclic voltammogram (CV) recorded at the basal plane displays a stable and low background current without redox peaks until a slow reduction current for HER is observed with a high overpotential at approximately −1.15 V vs Ag/AgCl QRCE. This confirms that the edge sites of MoS₂ have high redox activity and display distinctive cyclic voltammogram (CV) characteristics due to the presence of exposed Mo⁴⁺ and sulfur defects.

The CV at the ITO surface (Point 4) shows HER at −1.2 V vs. Ag/AgCl QRCE, implying less catalytic activity of ITO. The high cathodic potential has also reduced the surface In³⁺/Sn⁴⁺ to a lower oxidation state, evident from the double oxidation peak-0.8 V generated by partial oxidation of the reduced ITO species, as discussed in detail at the earlier stages of this chapter. However, the reduction current response is higher than that of the MoS₂ surface because the surface conductivity of ITO is higher than the conductivity of the thin MoS₂ layer. The in-plane conductivity of MoS₂ is around 2000 times higher than the vertical direction. The conductivity in MoS₂ is low in the vertical direction due to the weak van der Waals force that holds the MoS₂ planes together. As the MoS₂ is attached to the ITO surface and no special measures were taken to connect the top surface of MoS₂ directly to the ITO surface (Ag paste), low electron mobility along the vertical direction lowers the conductivity of the top MoS₂ plane exposed to the electrolyte.

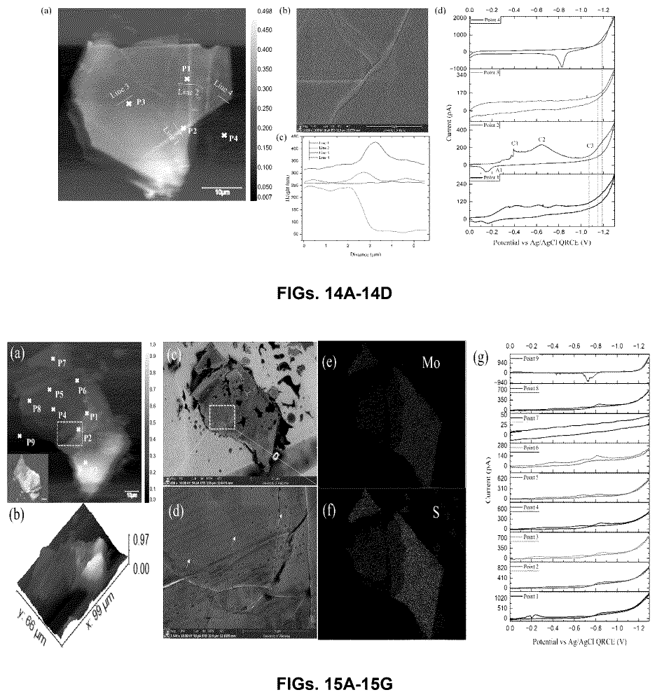

A variation in electrochemical activity is observed while investigating MoS₂ flake on the ITO substrate. The TF-SECCM topographical image of the scanned MoS₂, shown in FIG. 15A reveals a rough surface with significant defect sites. The image reveals a textured surface characterized by steps, edges, defects, and distinct edge sites, as further detailed in FIG. 15B. The correlated SEM micrograph confirms the roughness of the scanned MoS₂ surface (FIG. 15C). The zoom-in SEM micrograph reveals the line scan profile during the topographical mapping of TF-SECCM (FIG. 15D).

The elemental mapping shows the presence of Mo and S at the scanned surface, confirming the scanned flakes are MoS₂. The voltametric measurements taken at different point locations show distinct reduction current responses. All the CVs taken at the edge plane of the MoS₂ show a high current response with an onset potential at around-1.08 V vs Ag/AgCl QRCE. However, the CV taken at point 7 shows no current response. AFM topography and correlated SEM micrography confirm that point 7 is on a basal plane of the MoS₂, indicating the catalytic inertness of the basal plane. The HER onset potential at the edge sites varies at various point locations, indicating different catalytic activity at those locations that might be attributed to the variations in sulfur vacancies, Mo, and defects. Additionally, the voltammogram taken at the ITO surface shows distinct CV characteristics, having an In/Sn oxidation peak at −0.8 V vs Ag/AgCl QRCE. The CV also confirms that the HER reaction at the ITO surface requires high overpotential compared to the MoS₂. This observation demonstrated that different point locations have redox activity variation. Additionally, the second MoS₂ flakes show more reduction correct response for the HER compared to the previous one (FIG. 14A), although both of the flakes were synthesized at the same time on the same ITO substrate using the scotch tap exfoliation method. This variation of electrocatalytic activity is because of the surface roughness of the flakes, as the second one has more defect sites than the first one.

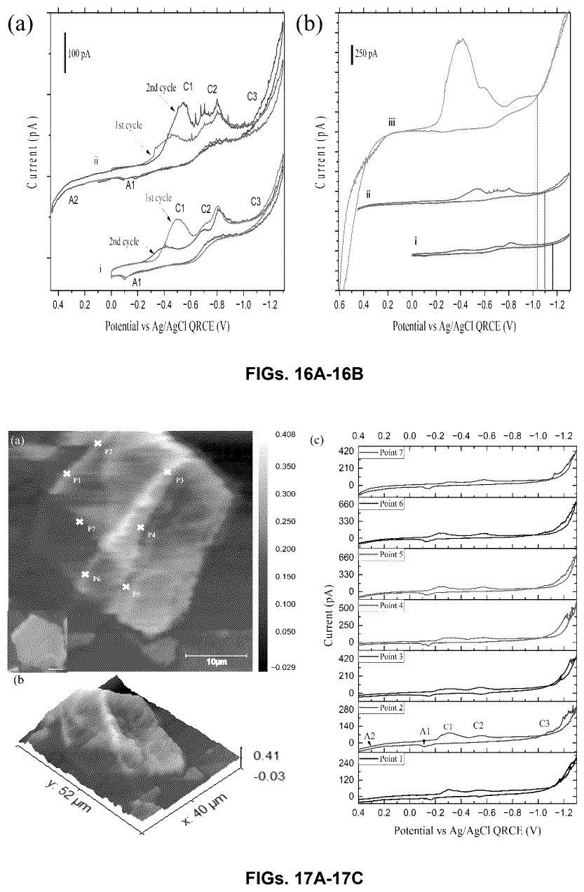

To understand the surface redox activity of MoS₂, CVs at the MoS₂ defect sites and basal planes at different point locations were performed. All the CVs for this study were taken at a starting potential of 0 V and scanned in the negative potential direction and then to positive polarization up to various potential limits. All the CVs taken at the defect show a characteristic feature distinct from those at the basal plane. Three characteristic reduction peaks are observed during the negative polarization denoted as C1, C2, and C3, illustrated in FIG. 16A (i).

During the forward scan, an oxidation peak is observed at potential-0.1 V vs Ag/AgCl QRCE. However, the redox peak current decreases in the consecutive backward scan starting from 0 V, indicating diminishing the oxidized species responsible for the reduction reaction. Moreover, the current reduction response for HER was also decreased in the second scan. To confirm the source of the C1 and C2 reduction peaks, the surface was scanned positively after the first scan, and it was observed that the peak currents of C1 and C2 increased, as shown in FIG. 16B (ii). Additionally, the current response for the HER has also increased. This observation clearly shows a relation of the reduction current for C1 and C2 with the oxidation of the surface. When polarization started from 0 V, the surface MoOs oxide layer was reduced from Mo(VI) to Mo(IV) at C1, and Mo(IV) was reduced to Mo(III)/Mo(II) at C2. Meanwhile, Mo(III)/Mo(II) was partially oxidized to Mo(IV) at A1 in the forward polarization. However, during the consecutive backward polarization starting from 0 V, the peak current at C1 decreases, indicating the lower thickness of the MoOs layer, which is already reduced in the previous negative scan. However, the peak current at C2 does not show a drastic decrease in the presence of exposed Mo(IV) at the edge sites of the MoS₂. When the surface is oxidized up to −0.4 V before the backward scan, an increase of C1 and C2 peak currents was observed. This is due to the oxidation of Mo(IV) to Mo(VI) at high positive polarization potential. This is evident from the high reduction peak at C1, indicating a thick MoOs film formation during oxidation. The reduction current response for HER has increased after oxidation treatment. That motivates us to study the effect of positive polarization potential on HER at the MoS₂.

The CV indicated by i in FIG. 16B shows a low HER reduction current response with an onset potential in a more negative direction, indicating decreased catalytic activity toward HER. However, when the positive potential limit increased in ii up to 0.4 V vs Ag/AgCl QRCE, an oxidation current is observed with an onset potential at 0.3 V. Subsequent backward polarization shows a high reduction current response for HER with the onset potential moved to a positive direction at −1.09 V. Another interesting reduction peak was observed a −0.53 V. This reduction peak was observed to shifted towards −0.41 V with a huge reduction current response when the forward scan potential increased to 0.6 V. Form this observation, it can be stated that the reduction current has a relation to the oxidation potential limit and directly proportional to the oxidation current. The MoS₂ can be oxidized to Molybdenum Mo(IV), which further oxidized to form MoO₃ (Mo(VI)), while the sulfur can be oxidized to SO₄²⁻, S²⁻ and S₂²⁻ at high oxidation potential. Additionally, S²⁻ present in the freshly exfoliated MoS₂ can be oxidized to form S₂²⁻ and SO₄²⁻ even in ambient conditions. Moreover, metallic oxidation of Mo⁴⁺ leads to the formation of Mo(VI) by forming MoO₃, whereas the S²⁻ oxidized to S₂²⁻ using the following reaction mechanism during electrochemical oxidation:

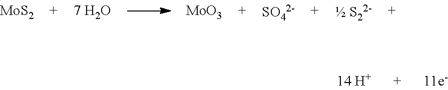

The reduction observed at −0.4 V during subsequent negative polarization can be attributed to Mo(VI) reduction to Mo(IV) and then from Mo(IV) to Mo(III/II). The reduction current response attributed to HER increased with onset potential shifting towards a positive direction, indicating an improved catalytic effect after oxidation pretreatment. The catalytic activity of MoS₂ for HER improved after oxidation pretreatment, which might be due to increased sulfur vacancy, doping of heteroatoms, and phase transition from semiconductor 2H—MoS₂ to metallic1T-MoS₂. Sulfur vacancies can accommodate protons, reduce the hydrogen adsorption energy, improve the hydrophilic character of the surface, and make better contact with electrolytes. During the oxidation polarization at a high potential limit, S vacancies are formed, which can also be replaced by oxygen; as a result, the transformation from 2H—MoS₂ into metallic 1T-MoS₂ occurs, and increased catalytic performance is observed. However, no observable catalytic reactivity improvement is observed if the positive potential is biased up to 0.35 V. From this observation, it can be stated that the phase transformation and defect sites creation occurred at the MoS₂ during the positive potential bias higher than −0.35 V vs. Ag/AgCl QRCE which enhanced the catalytic activity of the surface.

A high HER reduction current response was observed at vertically aligned MoS₂. The investigated area's 2D and 3D topographical images reveal surface roughness and vertical alignment (FIGS. 17A-17C). CVs taken at various point locations of the investigated area exhibit high current responses for HER, although with different onset potentials. The CVs reveal 3 reduction peaks, namely C1 and C2, which can be attributed to Mo(VI) to Mo(IV) and Mo(VI) to Mo(II/III) reduction, and HER, respectively. The oxidation peak observed during the forward scanning can be attributed to Mo(III)/Mo(II) formed during high negative potential from Mo(VI) at the edge sites. Another oxidation current during the forward scan starting at −0.35 is attributed to Mo(IV) oxidation to Mo(VI). The onset potential for the HER is observed to shift to the positive potential at point locations 4 and 5 compared to other locations, which implies that the efficiency of HER at all the edge sites is not equal.

### Example 3

Investigation of Local Photoelectrocatalytic Performance of p-Type Cu₂O and n-Type Au@TiO₂ for Water Splitting Reaction Via TF-SECCM.

Photoelectrochemical water splitting reaction to produce hydrogen is pivotal for transforming energy sources from fossil fuel to carbon-neutral clean fuel. A tandem electrochemical cell equipped with a p-type semiconductor photocathode for HER and an n-type photoanode for OER is a prominent way to harness solar energy by converting it into chemical fuels. Various semiconductor-based materials have been investigated for efficient solar energy conversion. Cuprous oxide (Cu₂O) is a p-type semiconductor that has gained considerable attention for its potential as a photocathode in photoelectrochemical cells, offering a promising approach for solar hydrogen fuel generation. Alternatively, n-type TiO₂ in the form of nanowires, nanorods, and nanoparticles has shown promising performance as a photoanode. The photocatalytic performance of the TiO₂ can be modified by plasmonic nanomaterials (e.g., Au, Ag) deposition at the surface due to light scattering of the plasmonic nanoparticles, scattering extends the path length of light within the TiO₂, leading to greater light absorption and, consequently, enhancing the photocatalytic activity. However, the photoelectrochemical performance of the photocatalysts based on bulk ensemble measurements suffers several limitations, such as 1. poor stability of photocatalysts under photoelectrochemical conditions, 2. measuring average properties of a photocatalyst sample, potentially obscuring heterogeneity and individual performance differences among particles or sites, 3. mass transport limitation in bulk measurement system can skew result by not providing the intrinsic photocatalytic activity of the particles, 4. interference from the bulk material and background signals, etc. This examples investigates the heterogeneity of local surface photo redox activity of electrodeposited Cu₂O film and hydrothermally grown TiO₂ NRs using the disclosed herein tuning fork scanning electrochemical cell microscopy (TF-SECCM). The method is based on a scanning pipet microscopy (SPM) approach disclosed herein and facilitated by localized linear scan voltammetry (LSV) measurements, allowing the investigation of surface redox heterogeneity of Cu₂O and TiO₂ without requiring complete substrate immersion in electrolyte solution. TF-SECCM provides a real topographical mapping of the surface and rapid localized photoelectrochemical information by performing LSV under intermittent light conditions at the point of interest to reveal variation in local photoelectrochemical activities across the surface in air. TF-SECCM results illustrate a significant variation in photocurrent responses of any region of interests (ROIs) across the Cu₂O and TiO₂ film with potential to fully reveal local photoelectrochemical activity dependence on single crystal structure and orientations, intrafacet junctions, and structural defects.

### Photoelectrochemical Water Splitting for Hydrogen

Semiconductor-based photoelectrochemical systems such as solar water splitting and CO₂ reduction are among technological advancements for solar energy harvesting, conversion, and storage to chemical fuels. They represent alternatives to replace fossil fuels to address global energy and environmental challenges for a sustainable future. Solar water splitting would yield high energy density hydrogen and is a carbon-neutral process in which a robust and cost-effective photoelectrochemical system is developed. Various material synthesis and heterostructure design strategies have been developed to improve photoelectrochemical water-splitting efficiencies. As reported earlier, n-type metal oxide electrodes with plasmonic metal and nanostructuring can enhance photoelectrochemical water splitting. P-type semiconductors can be used as photocathodes to reduce protons for hydrogen. The potential of tandem cells for unassisted water splitting using photoanode and photocathode in series connection is a promising strategy for efficient solar energy harness. Various n-type semiconductor materials are investigated as photoanodes to facilitate the photoelectrochemical conversion of water into O₂. N-type TiO₂ film is one of the promising photoanodes for its cost efficiency, non-toxicity, and earth abundance. The photocatalytic performance of TiO₂ can be improved by nano-structuring the surface and modification with plasmonic nanomaterials.

### Photoelectrochemical Properties of Cu₂O

Cu₂O is a promising photocathode for hydrogen production and CO₂ reduction into valuable chemical fuels due to its earth abundance, easy and scalable synthesis, p-type semiconducting nature, and a direct band gap of 2 eV, enabling it to absorb a wide visible spectrum (300-600 nm) region. Its conduction band is positioned above the reduction potential of water, making it suitable to facilitate the generation of H₂ with minimal or no external bias in a photoelectrochemical (PEC) cell.

Cu₂O exhibits a theoretical maximum photocurrent of 14.7 mA/cm² and achieves a light-to-hydrogen conversion efficiency of 18% when tested under the AM 1.5 solar spectrum. Upon light exposure, the excited electrons in the Cu₂O photocathode are driven toward the electrode-electrolyte interface, while the holes move into the bulk of the semiconductor due to the band bending in the p-type material.

The photoelectrons facilitate the H⁺ reduction to H₂ while the hole transports to the anode and completes the electrochemical circuit by water oxidation. However, utilizing Cu₂O as a photocathode is challenging because of its poor stability in an aqueous solution. The redox potential of monovalent Cu¹⁺ lies within its band gap, making it highly susceptible to photocorrosion, especially under potential bias. Most photoelectrochemical measurements on Cu₂O require an electrolyte solution to interface with a substantial Cu₂O film area. Consequently, this exposure often leads to the reductive decomposition of Cu₂O. The instability issue of the Cu₂O can be partially addressed by coating a protection layer on the film, such as surface coating with MoS₂ synthesized from spin coating a [Mo₃S₇(S₂CNEt₂)₃]| precursor combined with a thermal annealing process can partially address this issue. The nanoneedles of Cu₂O modified with carbon would help stabilize the electrode. Previously reported data quantified the electrode performance with an ensemble averaging method with missing details such as spatial heterogeneities and the effects of crystal structure and orientations, intrafacet junctions, and structural defects.

Cu₂O is also an interesting photocatalyst for CO₂ reduction reactions in aqueous solutions because of its narrow band gap, suitable valance, and conduction band energies. The presence of Cu¹⁺ at the surface favors the formation of C2 products. Photo-generated excited electrons at the semiconductor-electrolyte interface can effectively reduce inert CO₂ into chemical fuels such as CO, CH₄, CH₃OH, CH₃COOH, and HCOOH with low overpotential. Nonetheless, the enduring challenge of employing Cu₂O for CO₂ reduction lies in its susceptibility to photo corrosion. Applying a protective layer to modify the surface can enhance stability but may influence the complex CO₂ reduction process by modifying the surface active sites and pathways for molecule adsorption and desorption, ultimately affecting the selectivity of the resulting products.

Studying the pure Cu₂O surface is crucial to thoroughly understanding the CO₂ reduction mechanism at the Cu₂O surface and the rational engineering of the photocatalysts. However, macro photoelectrochemical (PEC) systems have inherent limitations, where the scanning probe electrochemical technique can be instrumental. It was shown that the grain boundary terminations are more active than the grain surface in gold catalysts for CO₂ to CO reduction using SECCM. SECCM was previously employed for electrochemical screening of polycrystalline Cu for CO₂ reduction reaction. However, these studies mainly focus on the electrochemical performance of the catalysts. Moreover, studying CO₂ reduction using a micro pipette-based technique requires system isolation from the environment for CO₂ saturation, as direct CO₂ purging in the electrolyte is challenging due to the formation of bubbles.

### Photoelectrochemical Properties of TiO₂.

N-type TiO₂ is a promising photoanode for water oxidation reactions because of its excellent electronic and chemical properties. The valence band of TiO₂ is well above the oxidation potential of the water-splitting reaction, which facilitates water oxidation under light illumination. However, bare TiO₂ shows photoactivity only in the UV spectrum range due to photogenerated electrons requiring high energy to overcome its large band gap (3-3.2 eV), which only covers 4% of total solar energy. When TiO₂ is immersed in an electrolyte, the charge transfer occurs between the photoelectrode and electrolyte interface because of the variations in energy levels. The charge transfer continues until the Fermi energy level of the photoelectrode is aligned with the Fermi energy level of the electrolyte, which causes the band-bending of the photoanode in the upward direction. Under light illumination, the absorbed light produces a photo-excited electron-hole pair in the photoanode. h⁺ in the n-type photoanode travels towards the electrode-electrolyte interface due to the upward band bending and oxidizes water to O₂ while the e moves towards the FTO, carried by the external circuit, and finally reaches the cathode to carry out HER. However, the photocurrent density heavily depends on the illumination intensity, charge separation efficiency, and charge transfer to the electrode/electrolyte interface. Different methods have been adopted to enhance the light absorption and charge separation efficiency of TiO₂, such as nanostructuring the surface, co-catalyst doping, and plasmonic nanomaterial incorporation. Surface modification of TiO₂ with plasmonic nanomaterials (e.g., Au, Ag) is a promising technique to enhance light absorption efficiency and photocatalytic activity. Plasmonic nanomaterials can show surface plasmon resonance (SPR) under external electromagnetic radiation due to the collective oscillation of the conduction band electrons. If the wavelength of the incident light is larger than the dimension of the particles, then the resonance is localized at the surface, referred to as the local surface plasmon resonance. The collective oscillation of the conduction band electron enhances the electromagnetic field near the surface, which decays exponentially perpendicular to the surface. Plasmonic nanomaterials decorated semiconductors show high photocatalytic activity due to the following reasons: 1. light scattering by plasmonic nanoparticles extends the light path length in TiO₂ and help increase light absorption, 2. plasmonic nanoparticles can act as a trap for photogenerated holes and reduce the possibility of photogenerated electron-hole recombination, 3. due to their excellent catalytic activity, plasmonic nanoparticles can increase the catalytic performance of TiO₂, which otherwise has sluggish kinetics for OER, 4. the light absorption spectrum can be extended from UV region to visible light region, and 5. plasmonic nanomaterials can enhance the conduction band electron population of the semiconductor by directly or indirectly injecting hot electrons. However, these metals suffered from corrosion and oxidation during the photochemical performance investigation using a bulk PEC measurement system.

### SECCM for Resolving Heterogeneities in Photoelectrochemical Properties.

Scanning Electrochemical Cell Microscopy (SECCM) is an advanced analytical technique that integrates electrochemical principles with scanning probe microscopy techniques. It employs a mobile micro/nano pipette with dimensions ranging from hundreds of nanometers to tens of micrometers. The pipette is filled with an electrolyte solution containing an electroactive species, with a quasi-reference counter electrode (QRCE) inserted from the back end of the pipet. Localized electrochemical measurements of local redox activities and surface conductivity with spatial resolutions reaching the nanometer scale can be achieved in air or other controlled environments. Recent publications have shown that SECCM can be applied to visualizing photoelectrochemical processes at the nanoscale.

For example, SECCM can reveal special heterogeneities and edge-type defect site effects in photoelectrochemical activities of 2D MoS₂ when combined with a light source. To understand the role of chemical and structural defects in semiconductor materials, which commonly act as recombination centers various techniques, such as a Carrier Generation-Tip Collection (CG-TC) SECCM technique were explored in the past. It should be noted that all reported SECCM measurements operate at a constant height mode or current feedback mode to estimate a sample's surface morphology. It is quite challenging to obtain the real morphology of a sample with these reported operation modes.

In this example, we will investigate heterogeneities in local photoelectrochemical activities of electrodeposited p-type Cu₂O photocathode and n-type TiO₂ photoanode along with topography mapping using the disclosed herein Tuning-Fork SECCM (TF-SECCM) technique. TF-SECCM utilizes the shear force response of a tuning fork sensor modified with a nanopipette to approach the surface and can rapidly obtain both morphological and photoelectrochemical information of any Regions of Interest (ROIs) upon force engagement of the tip to Cu₂O surface through a ~fL liquid droplet. We demonstrated that TF-SECCM can perfectly resolve surface morphology and provide critical insights into photoelectrochemistry related to surface structure and orientation, all with high temporal resolution. Our study shows that the photoelectrochemical performance and stability of electrodeposited Cu₂O films depend on the variations in local structure in crystal structure and orientations, intrafacet junctions, and structural defects.

### Experimental

Chemicals. The following chemicals were utilized as received without additional purification: Copper sulfate anhydrous (Alfa Aesar), lactic acid (Alfa Aesar), sodium sulfate anhydrous (VWR chemicals, LLC), sodium hydroxide (BeanTown chemical), ethanol, acetone (Fisher Scientific), hydrochloric acid (BDH chemicals), and nitric acid (BDH chemicals). All solutions were prepared using deionized water (resistivity approximately 18 MΩ-cm at 25° C.). A commercially available fluorine-doped tin oxide-coated transparent glass substrate (FTO, 24.5-27.0 Ω/cm, 1.5 cm×1.5 cm) with 1 mm thickness was used, onto which Cu₂O film was electrodeposited.

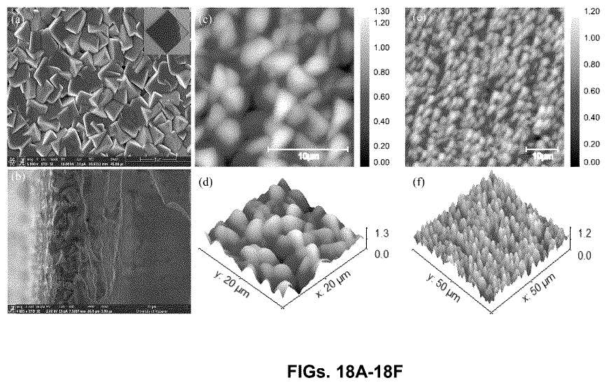

Electrodeposition of Cu₂O films. Before electrodeposition, the FTO substrates underwent successive cleaning steps using detergent, followed by acetone, ethanol, and deionized water in an ultrasonic bath, each for 20 minutes. Subsequently, they were dried with a stream of Argon gas and treated with UV-ozone for 15 minutes. The electrodeposition of Cu₂O was performed using a slightly modified method from the literature. Briefly, Cu₂O was electrochemically deposited from a lactate-stabilized solution (pH=11.0) comprising 0.4 M CuSO₄ and 3.0 M lactic acid. Complexing with lactate ions stabilizes copper and allows for the elevation of the pH to approximately 11 using a 5 M NaOH solution. The basic pH environment was used to ensure that the Cu₂O electrodeposited had p-type conductivity properties. The electrodeposition was conducted at room temperature using an electrochemical workstation, CHI760C (CH Instruments, Inc., Austin, TX), in a three-electrode configuration employing bulk electrolysis with coulometry technique in a stirred solution. The FTO glass substrate served as the working electrode, a graphite rod as the counter electrode, and a platinum coil as a quasi-reference electrode. Cuprous oxide (Cu₂O) deposition occurred at −0.3 V vs. Pt, accumulating a total charge of approximately 4.5 C within 2 hours. SEM micrograph of the electrodeposited Cu₂O film shows macro cube crystal formation at the FTO substrate (FIG. 18A). The topographical image collected by the FT-SECCM surface scanning of the Cu₂O film exhibits the capability of the TF-SECCM to resolve surface structure perfectly (FIGS. 18C-18F). A cross-section SEM image of the film shows approximately 2.8 μm thick film formation at the FTO surface after 4.5 C of charge accumulation (FIG. 18B).

Au Modified TiO₂ nanorod electrode. TiO₂ nanorods (NRs) were synthesized in situ on FTO glass using a standard hydrothermal method. Cleaned 2 cm×2 cm FTO glass slides served as substrates, undergoing sequential sonication in a detergent solution, acetone, ethanol, and deionized (DI) water for 20 minutes each. These substrates were partially covered with PTFE tape and placed vertically at the base of a 25 mL Teflon-lined stainless steel autoclave. A precursor solution, consisting of 0.3 mL titanium (IV) butoxide and 20 mL 18.5% wt. HCl, was introduced into the autoclave. The hydrothermal reaction was conducted at 180° C. for 4 hours in an electric oven. After cooling to room temperature, the samples were thoroughly rinsed with DI water and subsequently annealed at 450° C. in air for 2 hours. Gold (Au) layers with thicknesses of 1, 10, and 50 nm were then deposited on the prepared TiO₂ nanostructures (referred to as Au1@TiO₂, Au10@TiO₂, and Au50@TiO₂) using an electron beam evaporation system. The deposition occurred at a rate of 1 Å per second under a vacuum pressure of approximately 5×10-6 Torr. Finally, the annealing of the Au@TiO₂ samples was performed at 450° C. in the air for 1 hour.

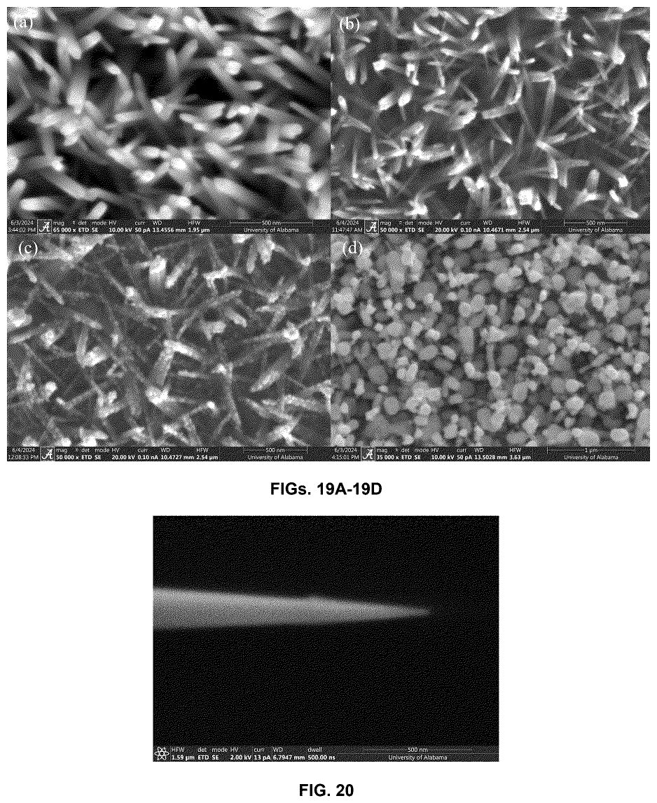

The SEM micrograph of the as-prepared TiO₂ shows vertically aligned TiO₂ nanorods at the surface (see FIGS. 19A-19D). The diameter of the TiO₂ nanorods varied from 30 to 85 nm. The SEM image of Au1@TiO₂ shows the presence of Au nanoparticles attached to the TiO₂ NRs wall. The Au nanoparticles were observed to increase in Au10@TiO₂. The nanoparticles are well distributed along the TiO₂ NR structure. A larger size of Au NPs with various shapes was observed in 50 nm Au50@TiO₂ NR. Additionally, the Au NPs are attached to the top of the TiO₂ NR, obscuring the TiO₂ NR underneath.

Fabrication of nanopipette electrode. Nanopipettes were fabricated from quartz capillaries (O.D.: 1.0 mm, I.D.: 0.70 mm, Length: 10 cm) using CO₂ laser puller equipment (P-2000, Sutter Instrument). Before pulling, the exterior of the quartz capillaries was cleaned using acetone to remove any potential contamination. The SEM of pulled pipette can be seen in FIG. 20. A two-lined program (HEAT=700 FIL=4 VEL=55 DEL=180 PUL=80, HEAT=700 FIL=4 VEL=60 DEL=150 PUL=120) capable of pulling the nanometer range pipette was employed. Thus, the pulled pipette was filled with 2 mM Na₂SO₄ electrolyte solution (near neutral pH) from the back opening using a syringe. As the electrolyte solution was injected into the nanopipette, a meniscus formed at the solution/air interface due to capillary forces, hindering the complete filling of the nanopipette tip. The nanopipette was positioned on a metal stage to remove the air with the sharp tip protruding beyond the edges. The metal stage and the nanopipette were then placed on a hot plate set at 83° C. for 1 hour and 30 minutes. This gradual heating process increased the temperature toward the pipette tip, creating a temperature gradient that facilitated volume expansion of the electrolyte solution, effectively displacing the air. An electrical connection was established by inserting a 0.25 mm diameter Ag/AgCl through the back opening. The Ag/AgCl electrode was prepared by immersing a cleaned Ag wire (99.9% metal basis, Thermo Scientific) in a concentrated FeCl₃ solution for 5 minutes. An I-V measurement was conducted using a two-electrode configuration to confirm nanopore filling with the electrolyte. An asymmetric current response during potential scanning ensures contact of the bulk electrolyte solution with the electrolyte solution at the nanopipette tip. Here, the counter and reference electrode connections were made to the Ag/AgCl wire inserted into the nanopipette, while the working electrode was an Ag wire in the bulk 2 mM Na₂SO₄ electrolyte solution.

### Configuration of TF-SECCM for Multiscale PEC Study

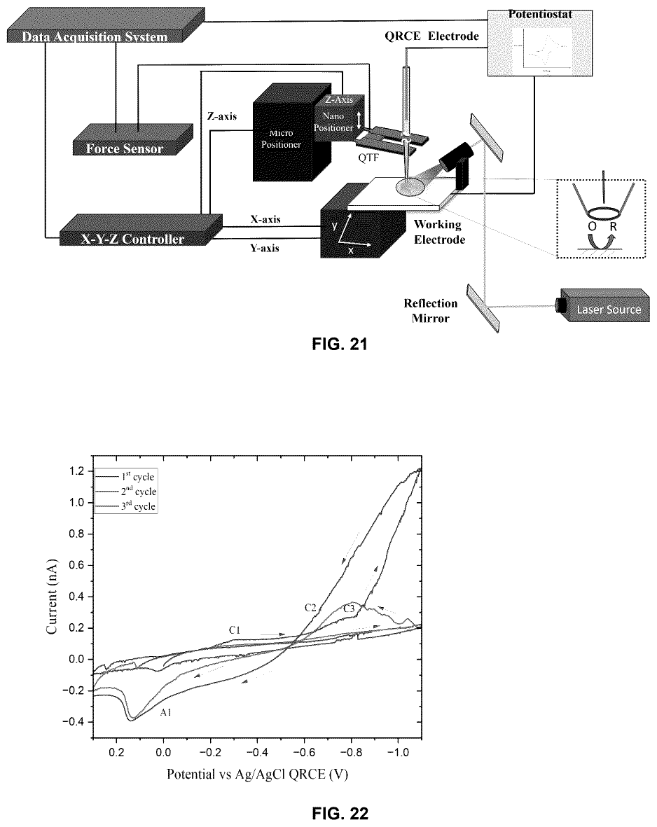

The TF-SECCM configuration, as illustrated in the schematic diagram in FIG. 21, was used for our multiscale PEC study. The nanopipette was attached to one tuning fork prong using our customized tip attachment system. The probe was further attached to the probe holder, which was connected to a z-axis piezo system. The sample was placed on a two-directional piezo system that could move the sample in an x-y axis direction during the raster scanning of the sample. The distance between the tip and the surface was precisely controlled by the quartz tuning fork force sensor and shear force operation mode. Upon touching the surface, a submicron electrochemical cell was formed at the tip-substrate contact point, which acted as a local electrochemical cell. The substrate acted as the working electrode, and an Ag/AgCl wire inserted inside the nanopipette from the rear orifice acted as the quasi-reference counter electrode of the system. A localized electrochemical reaction occurred after applying the two electrodes' potential difference. The TF-SECCM was equipped with a laser excitation system, with the laser light focused from the top of the sample. The diameter of the laser excitation was approximately 3 millimeters. However, the photocurrent response was exempt from the interference of neighboring atoms or photoactive sites as the electrochemical cell was very localized. All the electrochemical measurements were performed in air and at room temperature.

Upon arrival at the surface, the sharp nanopipette functions as an AFM probe to scan the surface and collect morphological information from the regions of interest (ROIs). During topographical mapping, the sample is raster scanned with an X-Y directional piezo-position controller, which enables accurate positioning while the tip remains stationary. Then, the tip is moved to specific ROIs to perform a photoelectrochemical analysis using conventional electrochemical methods. The system provides the local electrochemical signals free from interference of neighboring atoms via a tiny droplet protruding at the pipette apex. tuning fork to its resonance frequency.

### Results and Discussion

Characterization of Cu₂O film.

The surface morphology of Cu₂O film was analyzed using a scanning electron microscope (SEM, Apreo FE-SEM) equipped with energy dispersive X-ray (EDX). The Cu₂O film, with a thickness (approximately 2 μm) exhibited polyhedral cuboidal-shaped grains with well-defined edges, consistent with observations made previously by Shinde et al. The grain diameter ranged from >900 nm to 2.8 μm (FIG. 18B).

### Electrochemical Characterization.

The fundamental study of Cu₂O photoelectrochemistry using macro-electrochemical measurement methods is limited as it requires extensive sample preparation that consumes a significant amount of chemicals, time, and research effort. Surface modification of Cu₂O with a protective metal and non-metal oxide layer can reduce its corrosion activity. This layer prevents direct Cu₂O/electrolyte interface while maintaining and enhancing the hydrogen evolution reaction (HER) efficiency. Although Cu₂O has an intrinsic potential as a photocathode, the documented photocurrent falls significantly below theoretical predictions. Therefore, it is crucial to develop electroanalytical techniques with high special and temporal resolution specifically tailored for analyzing corrosion-sensitive materials like Cu₂O to gain a thorough insight into the PEC process of Cu₂O. This will facilitate an understanding of how the morphology, crystal structure, and defect sites influence the photocurrent response in photoelectrochemical experiments. To investigate the electrochemical characteristics of the electrodeposited Cu₂O, three consecutive cycles of CV measurement were performed using the TF-SECCM system, as shown in FIG. 22. During the backward polarization of the first CV cycle indicated by the black line, the reduction peak at −0.3 (indicated by C1) was missing. A small reduction peak was observed at −0.75 V, indicated by C2, while an oxidation peak was observed in the forward scan at 0.05 V. The reduction peak, C1, appeared during consecutive backward scans, and the reduction current for C2 was increased. Additionally, a cross-over was observed during the forward scan at −0.6 V, indicating the surface modification. Moreover, the oxidation peak A1 increased drastically with a peak potential shift to a higher potential. All the reduction and oxidation peak currents (C1, C2, and A1) increased in the 3^{rd} cycle with a significant reduction current at −0.82 V. From the observation, the first reduction peak at −0.3 V can be attributed to the reduction of Cu²⁺ to Cu₂O. The sample surface was initially covered with electrodeposited reduced Cu₂O film; thus, the C1 was missing during the first backward scan. The small oxidation peak observed during the consecutive forward scan (A1) can be attributed to the oxidation of Cu¹⁺ to Cu²⁺/Cu dissolution. The oxidized Cu²⁺ reduced to Cu₂O during the backward scan at −0.3 V, which is evident from the small reduction current that appeared in the 2^{nd} cycle. Moreover, at high negative polarization, the Cu¹⁺ converted to the metallic Cu at C2, which is apparent by the reduction in current cross-over at −0.6 V. The increased reduction-oxidation current for redox peaks with significant reduction current during the negative polarization with cross-over in the 3^{rd} scan shows an irreversible metallic transformation of the sample surface. Moreover, the high reduction current response at −0.82 V can be attributed to Cu¹⁺ to Cu transformation along with electrochemical HER (indicated by C3). This reduction current increased significantly after metallic Cu surface formation during high negative polarization further indicating the surface transformation from semiconductor to metal phase. This observation provides proof of limitation using a macro PEC measurement system for the corrosion-sensitive material like Cu₂O where the whole sample surface is exposed to the electrolyte and requires consecutive electrochemical measurement during which the surface irreversible transformation is evident.

### FT-SECCM Result and Discussion.

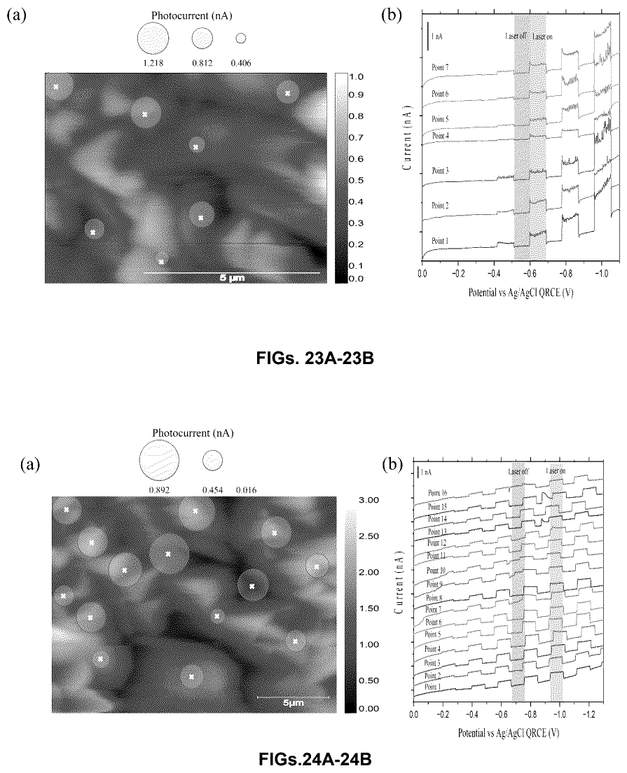

The conventional SECCM method utilizes constant height or current feedback to reveal complex redox activity at the surface with high spatial resolution, but it cannot provide actual morphological information. This limitation arises from its dependency on the current as the feedback signal and the challenges associated with topographical mapping in an array-based process. TF-SECCM can address this limitation by approaching the surface of Cu₂O through a TF force sensor and performing rapid electrochemical/photoelectrochemical measurements at the point of interest (POI). All the PEC measurements on the Cu₂O surface using TF-SECCM were conducted on the same 1.5×1.5 cm² sample to ensure coherency of the measurements with a nanopipette having a tip diameter of 180 nm. Typically, topographical mapping of a selected region of interest (ROI) is performed upon approaching the nanopipette at the surface with shear force guidance. Then, the nanopipette apex is retracted from the surface (about 10 μm), moved to the point of interest to execute the PEC study, and approached again with force control to minimize tip damage. Our approach shows excellent performance in revealing morphological variation across the surface, as illustrated in FIG. 23A. The topographical image provides a detailed visualization of the surface topography of an electrodeposited Cu₂O film. This image captures a range of surface features, from prominent elevations to deeper recesses, illustrating the intricate texture and structural variability inherent to the deposition process. Such disparities in surface topology indicate local variations in deposition conditions, possibly influenced by fluctuations in electrochemical parameters or substrate surface conditions. This initial topographic analysis is crucial for understanding the morphological properties of the Cu₂O film, which significantly impact its physical properties and functionality in photoelectrochemical performance. Following the detailed topographic analysis of the Cu₂O film, the photocurrent response measurements at designated points on the film were conducted under intermittent light exposure using a 488 nm light source (FIG. 23B). The traces captured from these points (P1 to P7) reveal significant variability in photocurrent, illustrating the impact of local surface features and composition on photoelectrochemical activity. Notably, the responses exhibit sharp increases and rapid stabilizations in photocurrent upon light activation, indicative of efficient electron-hole pair generation and separation. The bubble mapping of the photocurrent response at the specific point locations at the surface shows variation in photocatalytic activity specific to the surface electrochemistry and topography.

The second region of interest of the Cu₂O surface reveals a more intricate and varied topographic landscape, characterized by more pronounced and sharply defined grain boundaries and an evident increase in surface roughness (FIG. 24A). The topography mapping of the surface reveals crystal size variation with the presence of surface defects. This variation of crystal formation can be attributed to the intrinsic conductivity variation of the FTO substrate and applied electrochemical potential gradient across the surface. Moreover, LSV taken at different point locations (FIG. 24B) in this region reveals significant variation in photocurrent generation illustrated in the bubble map. The varying amplitudes and shapes of these peaks across different sample points indicate diverse photoelectrochemical behaviors, which might be attributed to localized variations in material properties such as thickness, crystallinity, intrinsic conductivity, and defect density. The difference in PEC response among these point locations indicates a variation of local surface electrochemistry at different crystals under laser excitation.

In the LSVs, at point locations 7, 9, 10, and 16, the reduction peak current at −0.7 V previously assigned to Cu¹⁺ to metallic Cu transformation is observed. A low photocurrent response with high background current is observed in these LSVs, which can be specified by the local surface electrochemistry of these point locations.

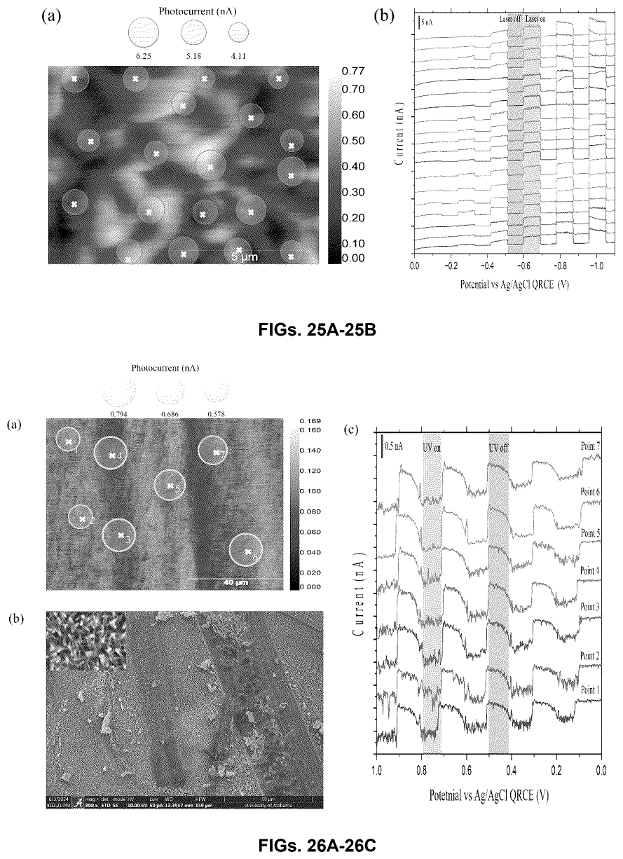

FIG. 25A shows the topographical image of the ROI 3 of the electrodeposited Cu₂O film, which exhibits a notably complex and heterogeneous surface topography characterized by a diverse array of grain sizes and pronounced height variations, which are distinctly captured in the range from 0.50 to 3.00 micrometers. The surface features more defined grain boundaries and notable depressions, suggesting voids or regions of lower deposition within the matrix. Such variability might indicate fluctuations in local deposition rates or variations in the chemical environment during the growth process. The LSV (FIG. 25B) illustrates the photocurrent responses from various point locations on the Cu₂O film, as highlighted in the topographical image. The bubbles overlapped on the topographical image represents the photocurrent responses of the specified points of interest at −0.96 V after dark current subtraction extracted from the LSVs from FIG. 26B. The variability in the magnitude and shape of the peaks across different traces indicates how microstructural differences at each point influence the photocurrent. Points with higher and more sharply defined peaks likely correspond to areas of the film with superior crystallinity or reduced defect densities, which facilitate more efficient charge separation and transport. In contrast, the locations exhibiting lower or more erratic peaks may suggest regions with higher defect concentrations or suboptimal crystalline structures, adversely affecting their photocurrent response. The variation in the obtained photocurrent response originates from the difference in single crystal structure and orientation, interface junction and structural defects, and variation in liquid electrolyte droplet sizes, which are associated with surface roughness and hydrophobicity. Future work will need to address the various contributions with the hope of deconvoluting each of these contributions.

### 5.4.4 Localized Photo Electrochemistry at Au-Coated TiO₂ Nanorods.

Titania (TiO₂) is an n-type semiconductor investigated thoroughly for solar energy harvesting by photoelectrochemical water splitting reaction due to its cost efficiency, thermal stability, electrical properties, catalytic activity, and low toxicity. The investigation explores the photoelectrochemical performance of bare TiO₂, featuring surface nanostructuring such as TiO₂ nanoparticles, nanowires, nanotubes, and nanorods to increase active surface area and enhance photocatalytic performance.

Furthermore, the TiO₂ is modified with plasmonic nanomaterials (Au, Ag, and Cu nanoparticles and nanowires) to enhance visible light absorption. Plasmonic nanomaterials can strongly interact with the incident light and exhibit LSPR. It can trap electrons and enhance efficient charge (electron-hole pair) separation. Furthermore, plasmonic nanoparticles can serve as direct active centers for catalytic reactions and thus enhance the electrocatalytic efficiency of the photocatalyst. The size, shape, and orientation of the plasmonic nanoparticles are reported to influence the light-absorbing efficiency of the semiconductor and, thus, influence the catalytic activity of the photocatalysts.

This example explores the capacity of the TF-SECCM approach to reveal the topography of the bare TiO₂ NR and Au NP-modified TIO₂ NRs, along with a photoelectrochemical performance at different points of interest in the scanned surface. The topographical mapping and photoelectrochemical investigation were performed with a nanopipette with a tip diameter of approximately 150 nm. The LSVs were carried out under intermittent UV excitation from the back of the sample with a UV lamp connected to the system.

The topographical mapping collected with TF-SECCM for the selected ROI at the bare TiO₂ NR sample shows a uniform surface with two depression lines present in the mapping (FIGS. 26A-26C). These depression lines indicate the surface scratch lines intentionally made at the surface, shown in the correlated SEM image of the scanned area. The SEM image of the scanned area shows the presence of a planer surface. However, the high-resolution SEM images show the presence of TiO₂ NR, which is not evident from the AFM topographical mapping. This is because the diameter of the as-grown TiO₂ NR varied from 30 to 85 nm, which is smaller than the diameter of the nanopipette used for the topographical investigation (~150 nm). Additionally, the gap between vertically aligned TiO₂ NRs is approximately 190 to 410 nm. The bigger nanopipette diameter might be the reason for not showing the individual TiO₂ NR in the topographic image. Nevertheless, the TF-SECCM can reveal overall surface texture, such as topographical heterogeneity on the surface. The micrograph confirms the presence of salt residue resulting from the solvent's evaporation at the investigated area, following topographical and electrochemical investigations conducted using TF-SECCM. The LSVs performed at designated point locations on a bare TiO₂ NR sample illustrate the photocurrent responses corresponding to specific locations identified in the topographic image. The responses are segmented into periods of UV light exposure (“UV on”) and non-exposure (“UV off”), as indicated by the orange and purple backgrounds, respectively. Upon UV illumination, an increase in photocurrent across all traces is observed. Without wishing to be bound by any theory, it was hypothesized that this increase underscores the material's capability to facilitate charge separation under light exposure. Notably, the photocurrent does not immediately return to baseline levels when the UV light is turned off, indicating a sustained charge separation and a slower recombination rate of photo-generated electron-hole pairs.

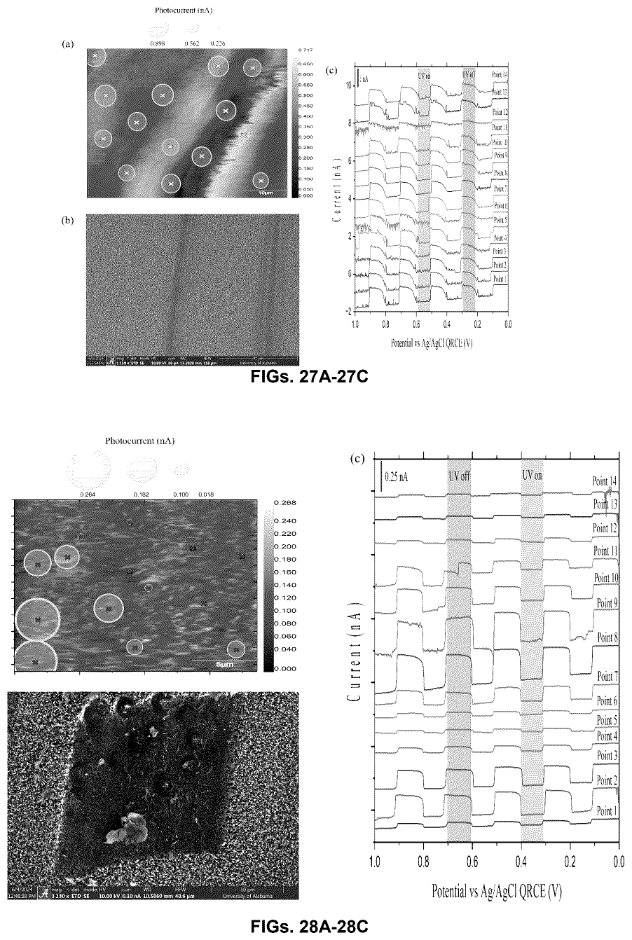

The noisy photocurrent responses and long relaxation time at the bare TiO₂ NRs can be attributed to the presence of deep and shallow defect sites in the TiO₂ NR in the form of Ti³⁺ and oxygen vacancies, which create trap states for charge carriers, leading to irregular recombination or transport behaviors that manifest as fluctuations in the current and slow charge recombination rate. The inconsistencies in charge carrier dynamics, such as irregular charge transport or intermittent charge separation, further contribute to the noise by causing variable rates of charge movement and recombination across the material. The photocurrent magnitude and decay kinetics variability among different point locations underscore non-uniform electronic properties across the sample. The TF-SECCM topographical image of Au1@TiO₂ reveals the scratch at the scanned surface (see FIGS. 27A-27C). The SEM image confirms the presence of such deliberately made scratches on the surface. The photocurrent response taken at different points on the surface shows distinct variation, indicating surface-bound photoelectrochemistry illustrated by the bubble graph in FIG. 27C. The Au1@TiO₂ showed a higher photocurrent response at the various point locations than the bare TiO₂ NR.

However, the photocurrent response under UV excitation decreases with the further increase of Au loading at the bare TiO₂ sample. The photocurrent response at different point locations of the Au10@TiO₂ sample shows a decrease compared to various locations at bare TiO₂ and Au1@TiO₂, with significant photocurrent variations among the point locations. (FIGS. 28A-28C).

Additionally, the 10 nm Au-coated TiO₂ nanorods exhibit a comparatively shorter relaxation lifetime, suggesting that the Au nanoparticles are well-distributed and serve as an electron reservoir. This arrangement efficiently prevents the photogenerated electrons from being trapped at the deep defects of the TiO₂. The topographical image of the investigated area shows a rough surface with some horizontally aligned Au10@TiO₂ NR with significant photocurrent variations at the specific POIs illustrated by the bubbles (see FIG. 28A). The correlated SEM image shows the presence of horizontally aligned nanorods on the surface after performing topographical scanning of the ROI (see FIG. 28B). Point locations 1, 4, 5, 6, 12, 13, and 14 show lower photocurrent response under UV excitation than other investigated locations at the surface. The variation in photocurrent responses might be attributed to the coverage of the TiO₂ NR with the Au NP. The increased coverage inhibits direct contact between TiO₂ nanorods and the electrolyte, affecting photocatalytic water-splitting reactions. The higher gold nanoparticle coverage in Au10@TiO₂ compared to Au1@TiO₂, suggests a more substantial influence on limiting the photocatalytic activity due to reduced exposure of TiO₂ to the electrolyte and electron trapped at the Au NPs. which might restrict the TiO₂ from directly contacting the electrolyte and decrease photocatalytic water-splitting reactions.

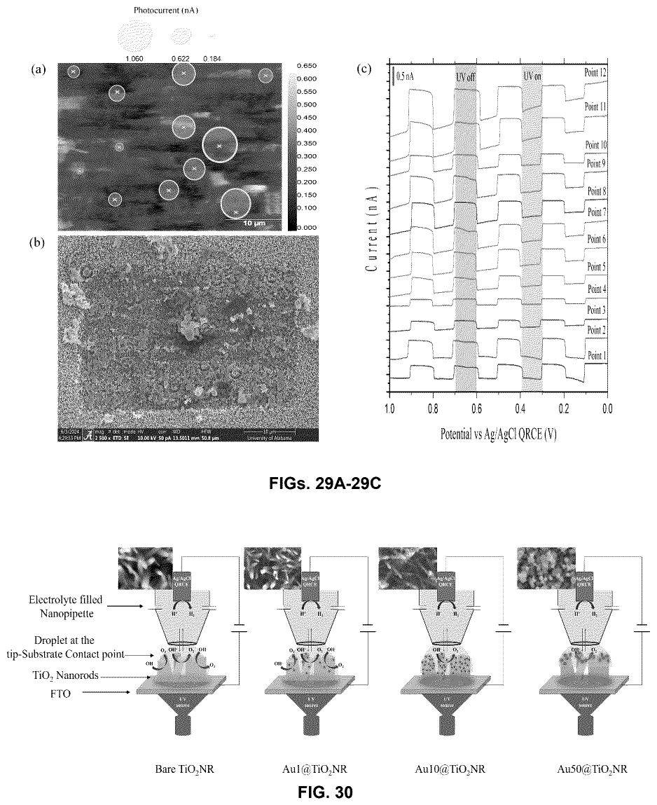

The topographic image of the Au50@TiO₂ NR shows a rough surface with a different surface texture than the previously investigated surface (see FIGS. 29A-29C). This might be due to the large size of Au NPs at the surface, which creates surface heterogeneity. The presence of large-sized Au NPs at the surface is evident from the correlated SEM image of the investigated surface area (see FIG. 29B). The large particle size of the Au and top orientation at the TiO₂ NR restricts direct electrolyte contact with the TiO₂ NR, thus decreasing the photocurrent response upon UV excitation. Moreover, a notable variation of photocurrent response at various point locations is observed in the Au50@TiO₂ sample. Point locations 3, 4, 5, and 10 show lower photocurrent response than other locations. It is evident from the observation that the heterogeneity in photocurrent response under UV excitation among various point locations increases with the increase of Au NP size, coverage of TiO₂ NR, and orientation (at the top or side wall attachment of Au NPs). The photocurrent response is higher in the point locations where dips in the topographical image are located, which might be because of the direct contact with the TiO₂.

As discussed earlier, the diameter of the nanopipette is larger than that of individual TiO₂ NRs. Thus, the photocurrent response collected at a specific point location is assumed to be the collective response of multiple NRs, as depicted in the schematic diagram in FIG. 29C. Electron-hole pairs are generated in the TiO₂ semiconductor upon UV excitation because incident light has enough energy to excite electrons from the valance band to the conduction band. At the semiconductor-electrolyte interface, the n-type TiO₂ experiences upward band bending, facilitating these charge carriers' separation and directional movement. The upward band banding causes the holes to move towards the semiconductor-electrolyte interface and oxidize water by accepting electrons to oxygen while the electrons in the conduction band move to the charge collector, which finally reaches the Ag/AgCl wire cathode through the external circuit and reduces proton to hydrogen. In bare TiO₂ NRs, multiple NRs might be exposed to the electrolyte through the protruded droplet at the tip apex. The photocurrent response at bare TiO₂ NR shows a sharp rise when exposed to UV light as electron-hole pairs are generated. However, the photocurrent shows an exponential decay of the photocurrent instead of a sharp drop back to the baseline. This tailing effect indicates the sustained presence of charge carriers, which are slowly recombining or trapped temporarily before recombination. The defect sites created in the TiO₂, such as Ti³⁺ and oxygen vacancies, might act as trap sites and reduce the charge recombination rate.

In the Au1@TiO₂ NR sample, the NRs are partially coated with Au NPs, as shown in FIG. 19B. These Au NPs can act as the electron reservoir and effectively separate charge carriers. A large area of the TiO₂ NRs is still contacting the electrolyte after coating. The synergistic effect of plasmonic Au NPs and TiO₂ NR increases the photocurrent responses at different point locations of the sample surface. However, a large portion of the TiO₂ NRs are covered by the Au NPs when the sample is coated with 10 nm Au as shown in FIG. 19C. Due to the well dispersion of the NPs at the TiO₂ NRs, the electrons cannot be trapped in the deep defect sites, and a faster relaxation lifetime is observed. Moreover, the excited electrons are trapped in the Au NPs reservoir, reducing the electron density in the TiO₂ and restricting the electrons from moving to the charge collector, which might contribute to the reduced photocurrent response of the TiO₂ with increased Au deposition.

Additionally, the protruded droplet size at the tip apex might contribute to the photocurrent response. The size of the droplet at the tip-surface contact point is influenced by the surface nature, especially the hydrophilic nature of the surface. Titanium dioxide (TiO₂) exhibits inherent hydrophilic properties due to the presence of surface hydroxyl groups that form hydrogen bonds with water molecules, enhancing water adsorption under ambient conditions. In contrast, gold nanoparticles (Au NPs) are intrinsically more hydrophobic but can be modified to be hydrophilic through surface functionalization. TiO₂'s hydrophilicity is significantly enhanced upon UV exposure through its photocatalytic activity; the UV-induced electron-hole pairs facilitate the formation of hydroxyl radicals, increasing the density of hydrophilic groups on the surface. (FIG. 30)

The well-distributed Au NPs in Au10@TiO₂ and large Au NPs at the tip of TiO₂ NR in Au50@TiO₂ samples might restrict direct contact of TiO₂ NRs to the electrolyte and decrease the photocurrent responses upon UV illumination. The significant variation in photocurrent response is observed at various point locations at the surface might also be due to the variation of TiO₂ NR NP coverage. Thus, the effect of droplet size in the photocurrent response is not trivial and requires an experimental design to understand the effect of these components in the photocurrent response.

### Exemplary Aspects

Example 1. A device comprising: a piezoelectric resonator; and a micro or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter, wherein the predetermined length is measured from a coupling point to the piezoelectric resonator, wherein the body of the micro or nano-sized reservoir comprises: (a) a first electrode; and (b) an electrolyte solution configured to at least partially disperse as a droplet from the tip on a surface of a substrate; wherein the predetermined length is selected to provide a Q-factor of the piezoelectric resonator of 500 Hz to 10 KHz.

Example 2. The device of any one of the examples herein, particularly Example 1, wherein the predetermined length is 10 micrometers to less than 10 mm.

Example 3. The device of any one of the examples herein, particularly Example 1 or 2, wherein the device comprises a receptacle configured to receive the piezoelectric resonator and the micro or nano-sized reservoir in the predetermined configuration.

Example 4. The device of any one of the examples herein, particularly any one of Examples 1-3, wherein the device is a microscope probe providing a topographical mapping and redox activity of the substrate surface.

Example 5. The device of any one of the examples herein, particularly any one of Examples 1-4, wherein a distance from the tip to the substrate surface is controlled by the piezoelectric resonator.

Example 6. The device of any one of the examples herein, particularly any one of Examples 1-5, wherein the device further comprises a stepper motor.

Example 7. The device of any one of the examples herein, particularly Example 6, wherein the stepper motor controls a distance from the tip to the substrate surface independently or in combination with the piezoelectric resonator.

Example 8. The device of any one of the examples herein, particularly any one of Examples 1-7, wherein the piezoelectric resonator is a tuning fork comprising two prongs.

Example 9. The device of any one of the examples herein, particularly Example 8, wherein the tuning fork comprises a stem coupled to a U-shaped fork.

Example 10. The device of any one of the examples herein, particularly Example 8 or 9, wherein the micro or nano-sized reservoir is coupled with one of the two prongs.

Example 11. The device of any one of the examples herein, particularly Example 10, wherein the micro or nano-sized reservoir is coupled to at least a portion of a distal end of the one of the two prongs with a fastener.

Example 12. The device of any one of the examples herein, particularly Example 11, wherein the fastener is an adhesive.

Example 13. The device of any one of the examples herein, particularly any one of Examples 1-12, wherein the body of the micro or nano-sized reservoir is substantially straight along a longitudinal axis perpendicular to the substrate surface.

Example 14. The device of any one of the examples herein, particularly any one of Examples 8-13, wherein the body of the micro or nano-sized reservoir is substantially straight along a longitudinal axis perpendicular to a surface of the two prongs.

Example 15. The device of any one of Examples 1-12, wherein a portion of the body of the micro or nano-sized reservoir is bent along a transverse axis forming a proximal bent portion and a distal straight portion, wherein the proximal bent portion of the body is substantially parallel to the substrate, and the distal straight portion extending into the tip is substantially perpendicular to the substrate.

Example 16. The device of any one of the examples herein, particularly

Example 15, wherein the distal straight portion is in plane with a surface of the two prongs.

Example 17. The device of Example 15 or 16, wherein the electrode is positioned within the proximal bent portion of the body.

Example 18. The device of any one of the examples herein, particularly any one of Examples 8-17, wherein at least a portion of the micro or nano-sized reservoir is vertically aligned with a prong surface while horizontally or vertically oscillating at a predetermined frequency above the substrate surface.

Example 19. The device of any one of the examples herein, particularly any one of Examples 4-18, wherein an electrochemical signal is collected at a tip-substrate surface contact point.

Example 20. The device of any one of the examples herein, particularly any one of Examples 1-19, wherein the first electrode is a quasi-reference electrode.

Example 21. The device of any one of the examples herein, particularly any one of Examples 1-20, wherein the substrate is a working electrode.

Example 22. The device of any one of the examples herein, particularly any one of Examples 1-21, wherein a distal end of an outer surface of the nano-sized reservoir is electrically conductive.

Example 23. The device of any one of the examples herein, particularly Example 22, wherein the electrically conductive distal end of the micro or nano-sized reservoir's body is a counter electrode.

Example 24. The device of any one of the examples herein, particularly any one of Examples 1-23, wherein a droplet size and/or shape are defined by the aperture diameter of the tip, hydrophobicity of the substrate surface, electrowetting properties of the substrate surface, the vibration amplitude of the nano-sized reservoir, the predetermined length of the nano-sized reservoir, of the or a combination thereof.

Example 25. The device of any one of the examples herein, particularly any one of Examples 1-24, wherein the droplet has a size of 10 nm 100 microns.

Example 26. The device of any one of the examples herein, particularly any one of Examples 4-25, wherein the device is operated in a shear force mode, tapping mode, or a combination thereof.

Example 27. The device of any one of the examples herein, particularly any one of Examples 1-26, wherein the device is configured to measure an electrical and/or electrochemical response and/or topography of the substrate surface with a spatial resolution from 10 nm to 100 μm.

Example 28. The device of any one of the examples herein, particularly any one of Examples 1-27, wherein the micro or nano-sized reservoir comprises two or more channels, wherein the first electrode is positioned within one of the two or more channels.

Example 29. The device of any one of the examples herein, particularly any one of Examples 1-28, wherein the micro or nano-sized reservoir comprises a micro or nanopipette.

Example 30. A system comprising the device of any one of the examples herein, particularly any one of Examples 1-29.

Example 31. The system of any one of the examples herein, particularly Example 30, further comprising a substrate, wherein the substrate comprises a test sample and wherein the test sample is electrically conductive, insulating, semiconducting, or a combination thereof.

Example 32. The system of any one of the examples herein, particularly any one of Examples 30-31, wherein the system further comprises a potentiostat.

Example 33. The system of any one of the examples herein, particularly any one of Examples 30-32, wherein the system further comprises a light source, one or more cameras, a spectrometer, a photodetector, one or more microscope objectives, or a combination thereof.

Example 34. The system of any one of the examples herein, particularly any one of Examples 30-33, wherein the system further comprises a controlling unit.

Example 35. A mounting device comprising: a first portion configured to receive an atomic-force microscope (AFM) probe, wherein the AFM probe comprises a tuning fork comprising two prongs; a second portion configured to receive a micro or nano-sized reservoir; the first and the second portions are aligned with each other such that when the tuning fork is mounted within the first portion, and the micro or nano-sized reservoir is mounted within the second portion, the micro or nano-sized reservoir is positioned substantially vertically to a distal end of one of the two prongs of the tuning fork.

Example 36. The mounting device of any one of the examples herein, particularly Example 35, wherein the AFM probe further comprises a PCB control board controlling the tuning fork, and wherein the first portion comprises a further portion configured to receive and mount the PCB control board.

Example 37. The mounting device of any one of the examples herein, particularly Example 35 or 36, wherein the second portion comprises one or more orifices disposed at a predetermined distance from each other, wherein the micro or nano-sized reservoir is configured to be mounted within one of the one or more orifices at a predetermined length relative to the tuning fork.

Example 38. The mounting device of any one of the examples herein, particularly Example 37, wherein the second portion comprises one or more fasteners configured to immobilize the micro or nano-sized reservoir within the orifice.

Example 39. The mounting device of any one of the examples herein, particularly any one of Examples 35-38, further comprising one or more of x, y, z, xy, xz, yz, or xyz micro-positioning controllers configured to align the micro- or nano-sized reservoir with the prong of the fork.

Example 40. The mounting device of any one of the examples herein, particularly any one of Examples 35-39, wherein when the micro or nano-sized reservoir is mounted in the second portion, and the tuning fork is mounted in the first portion, the micro or nano-sized reservoir and tuning fork are coupled with an adhesive.

Example 41. The mounting device of any one of the examples herein, particularly any one of Examples 35-40, wherein the micro or nano-sized reservoir comprises two or more channels.

Example 42. The mounting device of any one of the examples herein, particularly any one of Examples 35-41, wherein the micro or nano-sized reservoir is a micro or nano-sized pipette.

Example 43. A system comprising the mounting device of any one of the examples herein, particularly any one of Examples 35-42, further comprising one or more cameras, wherein the one or more cameras assist in mounting the micro or nano-sized reservoir and tuning fork with the mounting device.

Example 44. A method comprising: positioning a sample within a system comprising the device of any one of the examples herein, particularly any one of Examples 1-29, measuring at least one property of the sample, wherein the at least one property is selected from a sample roughness, topography, electrical response, electrochemical response, photocurrent, or a combination thereof.

Example 45. The method of any one of the examples herein, particularly Example 44, wherein the method further comprises chemical and/or electrochemical patterning of a surface of the sample.

Example 46. The method of any one of the examples herein, particularly Example 44 or 45, wherein the method further comprises correlating a surface morphology of the sample with a local redox property of the sample.

Example 47. The method of any one of the examples herein, particularly any one of Examples 44-46, wherein the method further comprises transporting a predetermined material to the sample.

Example 48. The method of any one of the examples herein, particularly any one of Examples 44-47, wherein the method further comprises quantifying local reactions on the sample.

Example 49. The method of any one of the examples herein, particularly any one of Examples 44-48, wherein the method further comprises chemical imaging of the sample.

Example 50. A method comprising positioning a tuning fork and a micro or nano-sized reservoir in the mounting device of any one of the examples herein, particularly any one of Examples 35-42, and coupling the nano-sized reservoir to the tuning fork, wherein the coupling is monitored by a dual-camera system.

Example 51. The method of any one of the examples herein, particularly Example 50, wherein the coupling comprises adhering a portion of the micro or nano-sized reservoir to a prong of the tuning fork.

Example 52. The method of any one of the examples herein, particularly Example 50 or 51, wherein the method further comprises vertically aligning positioning of at least a portion of the micro or nano-sized reservoir relative to the tuning fork.

Example 53. The method of any one of the examples herein, particularly any one of Examples 50-52, wherein the micro or nano-sized reservoir comprises two or more channels.

Example 54. The method of any one of the examples herein, particularly Example 53, wherein a first electrode is positioned within one of the two or more channels.

Example 55. The method of any one of the examples herein, particularly any one of Examples 50-54, wherein the micro or nano-sized reservoir comprises a micro or nanopipette.

Example 56. A method comprising: obtaining an AF morphology image of a sample at open circuit potential, wherein the image comprises one or more regions of interest (ROIs); moving the device of any one of any one of the examples herein, particularly Examples 1-29 to the one or more regions of interest; performing a cycling voltammetry at the one or more regions of interest to probe a local redox activity.

Example 57. The method of any one of the examples herein, particularly Example 56, wherein the step of collecting is performed while a droplet size is substantially without change.

Example 58. A device comprising: a piezoelectric resonator; and a micro- or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter, wherein the predetermined length is measured from a coupling point to the piezoelectric resonator, wherein at least a portion of an interior portion of the body of the micro or nano-sized reservoir and/or at least a portion of an interior portion of the tip comprises a conductive material; wherein the body of the micro or nano-sized reservoir comprises an electrode; wherein the predetermined length is selected to provide a Q-factor of the piezoelectric resonator of 500 Hz to 10 KHz; a distance from the tip to the substrate surface is controlled by the piezoelectric resonator; and wherein the device is operated in a shear force mode, tapping mode, or a combination thereof.

Example 59. The device of any one of the examples herein, particularly Example 57, wherein the conductive material comprises a metal, semiconductor, one or more conductive polymer layers, carbon-based materials, or any combination thereof.

Example 59. The device of any one of the examples herein, particularly Example 57 or 58, wherein the body of the micro- or nano-sized reservoir comprises an electrolyte.

1. A device comprising:
a piezoelectric resonator; and
a micro or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter,
wherein the predetermined length is measured from a coupling point to the piezoelectric resonator,
wherein the body of the micro or nano-sized reservoir comprises:
a) a first electrode; and
b) an electrolyte solution configured to at least partially disperse as a droplet from the tip on a surface of a substrate;
wherein the predetermined length is selected to provide a Q-factor of the piezoelectric resonator of 500 Hz to 10 KHz;
wherein a distance from the tip to the substrate surface is controlled by the piezoelectric resonator; and
wherein the device is operated in a shear force mode, tapping mode, or a combination thereof.

2. The device of claim 1, wherein the device further comprises a stepper motor, and wherein the stepper motor controls a distance from the tip to the substrate surface independently or in combination with the piezoelectric resonator.

3. The device of claim 1,
wherein the piezoelectric resonator is a tuning fork comprising two prongs,
wherein the tuning fork comprises a stem coupled to a U-shaped fork and
wherein the micro or nano-sized reservoir is coupled with one of the two prongs.

4. The device of claim 1, wherein the body of the micro or nano-sized reservoir is substantially straight along a longitudinal axis perpendicular to the substrate surface.

5. The device of claim 3, wherein the body of the micro or nano-sized reservoir is substantially straight along a longitudinal axis perpendicular to a surface of the two prongs.

6. The device of claim 1, wherein a portion of the body of the micro or nano-sized reservoir is bent along a transverse axis forming a proximal bent portion and a distal straight portion, wherein the proximal bent portion of the body is substantially parallel to the substrate, and the distal straight portion extending into the tip is substantially perpendicular to the substrate and wherein the distal straight portion is in plane with a surface of the two prongs.

7. The device of claim 6, wherein the electrode is positioned within the proximal bent portion of the body.

8. The device of claim 3, wherein at least a portion of the micro or nano-sized reservoir is vertically aligned with a prong surface while horizontally or vertically oscillating at a predetermined frequency above the substrate surface.

9. The device of claim 1, wherein an electrochemical signal is collected at a tip-substrate surface contact point.

10. The device of claim 1, wherein the first electrode is a quasi-reference electrode, and/or the substrate is a working electrode.

11. The device of claim 1, wherein a distal end of an outer surface of the nano-sized reservoir is electrically conductive, and wherein the electrically conductive distal end of the micro- or nano-sized reservoir's body is a counter electrode.

12. The device of claim 1, wherein the device is configured to measure an electrical and/or electrochemical response and/or topography of the substrate surface with a spatial resolution from 10 nm to 100 μm.

13. The device of claim 1, wherein the micro or nano-sized reservoir comprises two or more channels, wherein the first electrode is positioned within one of the two or more channels.

14. A system comprising the device of claim 1, wherein the system further comprises
a substrate, wherein the substrate comprises a test sample and wherein the test sample is electrically conductive, insulating, semiconducting, or a combination thereof.

15. The system of claim 14, wherein the system further comprises a potentiostat, and/or a light source, one or more cameras, a spectrometer, a photodetector, one or more microscope objectives, or a combination thereof.

16. A mounting device comprising:
a first portion configured to receive an atomic-force microscope (AFM) probe, wherein the AFM probe comprises a tuning fork comprising two prongs;
a second portion configured to receive a micro or nano-sized reservoir; and
the first and the second portions are aligned with each other such that when the tuning fork is mounted within the first portion, and the micro or nano-sized reservoir is mounted within the second portion, the micro or nano-sized reservoir is positioned substantially vertically to a distal end of one of the two prongs of the tuning fork.

17. A method comprising:
positioning a sample within a system comprising the device of claim 1,
measuring at least one property of the sample,
wherein the at least one property is selected from a sample roughness, topography, electrical response, electrochemical response, photocurrent, or a combination thereof;
wherein the method further optionally comprises chemical and/or electrochemical patterning of a surface of the sample, and/or correlating a surface morphology of the sample with a local redox property of the sample, and/or transporting a predetermined material to the sample;
and/or quantifying local reactions on the sample; and/or chemical imaging of the sample.

18. A device comprising:
a piezoelectric resonator; and
a micro or nano-sized reservoir coupled to at least a portion of the piezoelectric resonator and having a predetermined length and comprising a body having a predetermined volume and extending into a tip, wherein the tip defines a distal portion of the reservoir and has a predetermined aperture diameter,
wherein the predetermined length is measured from a coupling point to the piezoelectric resonator,
wherein at least a portion of an interior portion of the body of the micro or nano-sized reservoir and/or at least a portion of an interior portion of the tip comprises a conductive material;
wherein the body of the micro- or nano-sized reservoir comprises an electrode;
wherein the predetermined length is selected to provide a Q-factor of the piezoelectric resonator of 500 Hz to 10 KHz;
wherein a distance from the tip to the substrate surface is controlled by the piezoelectric resonator; and
wherein the device is operated in a shear force mode, tapping mode, or a combination thereof.

19. The device of claim 18, wherein the conductive material comprises a metal, semiconductor, one or more conductive polymer layers, carbon-based materials, or any combination thereof.

20. The device of claim 18, wherein the body of the micro- or nano-sized reservoir comprises an electrolyte.
